(19) United States
(12) Patent Application Publication
(10) Pub. No.: US 2018/0277661 A1
(43) Pub. Date: Sep. 27, 2018

(54) THIN FILM TRANSISTOR SUBSTRATE, MANUFACTURING METHOD FOR THIN FILM TRANSISTOR SUBSTRATE, AND LIQUID CRYSTAL DISPLAY

(71) Applicant: Mitsubishi Electric Corporation, Tokyo (JP)

(72) Inventors: Kensuke NAGAYAMA, Kumamoto (JP); Kazunori INOUE, Kumamoto (JP); Koji ODA, Kumamoto (JP)

(73) Assignee: Mitsubishi Electric Corporation, Tokyo (JP)

(21) Appl. No.: 15/916,002

(22) Filed: Mar. 8, 2018

(30) Foreign Application Priority Data
Mar. 23, 2017 (JP) 2017-056915

(51) Int. Cl. H01L 29/66; H01L 29/22; H01L 29/786; G02F 1/1368

(52) U.S. Cl. CPC H01L 29/66742; G02F 1/1368; H01L 29/78681; H01L 29/2206

(57) ABSTRACT

A first semiconductor layer is opposed to a first gate electrode with intermediation of a gate insulation film, and is formed of amorphous silicon. First and second contact layers each have a portion arranged on the first semiconductor layer, and are formed of an oxide semiconductor. A first electrode is connected to the first contact layer. A second electrode is connected to the second contact layer.

### BACKGROUND OF THE INVENTION

### Field of the Invention

The present invention relates to a thin film transistor substrate, a manufacturing method for a thin film transistor substrate, and a liquid crystal display, and more particularly to a thin film transistor substrate for a liquid crystal display, a manufacturing method for a thin film transistor substrate for a liquid crystal display, and a liquid crystal display.

### Description of the Background Art

A liquid crystal display (LCD), which is one of general thin display panels of the related art, has been widely used as a monitor of a personal computer and a mobile information terminal device or the like by utilizing its advantages of low power consumption, the small size, and light weight. In recent years, the LCD has also been widely used for application to a TV.

In particular, an active matrix substrate (hereinafter referred to as a “TFT substrate”) using a thin film transistor (TFT) as a switching element of a pixel is well known for its use as an electro-optical device such as an LCD. For an LCD using a TFT substrate (TFT-LCD), not only enhancement in display performance (realization of wide viewing angle, high resolution, high quality, and the like) is required, but realization of a lower cost is also required through simplification in a manufacturing process and efficient manufacturing.

A general TFT-LCD is formed by mounting a polarizer and the like to a liquid crystal panel as a basic structure. The liquid crystal panel includes a TFT substrate (element substrate), an opposing substrate (color filter (CF) substrate), and a liquid crystal layer sandwiched between the element substrate and the CF substrate. In the TFT substrate, a plurality of pixels including a pixel electrode and a TFT (pixel TFT) connected to the pixel electrode are arranged in a matrix pattern. The CF substrate includes a counter electrode arranged so as to be opposed to the pixel electrode of the TFT substrate, color filters (CFs), and the like. In a case of an LCD of a full transmission type, a backlight is typically provided on a rear surface side of the liquid crystal panel. In the liquid crystal panel in which the pixel electrode and the counter electrode for generating an electric field to drive liquid crystals are arranged so as to sandwich the liquid crystal layer as described above, there is a vertical electric field driving mode as typified by a twisted nematic (TN) mode, a vertical alignment (VA) mode, and the like. As other modes, a horizontal electric field mode in which both of the pixel electrode and the counter electrode are arranged in the TFT substrate is also used, and an in-plane switching (IPS) mode (“IPS” being a registered trademark) and a fringe field switching (FFS) mode are used typically.

Hitherto, in such a pixel TFT for an LCD as described above, an amorphous silicon (a-Si) film has been generally used as a channel layer of a semiconductor. The main reason therefor is that a semiconductor film having satisfactory uniformity in characteristics can be formed even on a large-area substrate, and that a low-cost glass substrate having low heat resistance can be used because a necessary processing temperature is comparatively low of being approximately 300° C. or below. For this reason, the use of an a-Si film as a channel layer of a pixel TFT is particularly suited for an LCD that has a wide display are and is required to reduce a cost as in application to a TV.

In a pixel TFT using an a-Si film as a channel layer, a TFT structure called an inverted staggered structure is typically used. When the inverted staggered structure is used, as in a manufacturing method disclosed in Japanese Patent Application Laid-Open No. 10-268353 (1998), for example, the number of times of photolithographic processes necessary for a manufacturing method for a TFT substrate of a TN mode or a VA mode can be decreased to five times, and therefore the TFT substrate can be manufactured efficiently at a low cost. The inverted staggered structure is based on a TFT structure called a BCE type that requires a back channel etching (BCE) process, and a BCE-type TFT using a-Si can be used suitably as a pixel TFT.

However, since mobility of a-Si is low of being about 0.5 cm²/Vsec, formation of even a channel layer of a drive TFT of a drive circuit for driving a pixel TFT with use of a-Si is fairly unpractical in view of the performance required for the drive TFT. Accordingly, generally, the drive circuit of an LCD is formed separately from a liquid crystal panel as a driving IC chip in which a TFT, a capacitive element, and the like are integrated. Then, the IC chip is mounted on the liquid crystal panel. For this reason, a space for mounting an external IC is required in a peripheral region of the liquid crystal panel. Requirement of an external IC chip is a major factor of limitation of reduction in size and price of LCD products.

On the other hand, when Si is made to be not amorphous but microcrystalline or polycrystalline, high mobility surpassing 10 cm²/Vsec can be obtained. In view of the above, in Japanese Patent Application Laid-Open No. 5-63196 (1993), for example, there is disclosed a technology of forming both of the pixel TFT and the drive TFT on the same substrate by using a polycrystalline Si layer as a channel layer. In this case, an external IC is not required, and the drive TFT can be manufactured using a photolithographic process similarly to the pixel TFT. Therefore, an LCD can be reduced in size, and a manufacturing cost can be reduced.

In more recent years, a TFT (oxide semiconductor TFT) using an oxide semiconductor as a channel layer has been developed (refer to Japanese Patent Application Laid-Open No. 2004-103957, Japanese Patent Application Laid-Open No. 2005-77822, and Kenji Nomura et al., “Room-temperature fabrication of transparent flexible thin-film transistors using amorphous oxide semiconductors,” Nature, 2004, vol. 432, pp. 488-492, for example). As the oxide semiconductor, there exist a zinc oxide (ZnO)-based one, an InGaZnO-based one obtained by adding a gallium oxide (Ga₂O₃) and an indium oxide (In₂O₃) to a zinc oxide (ZnO), and the like.

Through optimization of composition of the oxide semiconductor, a film in an amorphous state with satisfactory uniformity can be stably obtained, and mobility increased by one or more digits (5 cm²IVsec or more) compared to the related-art a-Si can be obtained. With this, an advantage of being able to realize a TFT having a small size and high performance is achieved. For this reason, the pixel TFT and the drive TFT can be formed on the same substrate also by using an oxide semiconductor film as a channel layer (refer to Japanese Patent Application Laid-Open No. 2011-29579 and Japanese Patent Application Laid-Open No. 2011-44699, for example).

As described above, formation of both of the pixel TFT and the drive TFT on the same substrate leads to reduction in size and cost of an LCD. As a channel layer of the pixel TFT, an a-Si film has been widely used as described above. However, mobility thereof is low, and hence application of the a-Si film to a channel layer of both of the pixel TFT and the drive TFT is unpractical.

Further, as disclosed in Japanese Patent Application Laid-Open No. 10-268353 (1998), in a case of manufacturing a BCE-type TFT of an inverted staggered structure using an a-Si film as a channel layer, satisfactory contact characteristics may not be obtained in an interface of the a-Si film as a channel layer and a metallic film as a source electrode and a drain electrode. For this reason, an n-type low-resistance Si semiconductor layer (ohmic contact layer) needs to be provided between the a-Si film and the metallic film. The n-type low-resistance Si semiconductor layer is formed by, for example, increasing electron carriers through addition of a group 13 atom, such as phosphorus (P), to a-Si. Therefore, after forming the source electrode and the drain electrode, a BCE process, which forms a channel (back channel) by removing an unnecessary n-type low-resistance Si semiconductor layer on the a-Si film, is required. In this case, the channel layer and the ohmic contact layer are formed of the same a-Si-based material. For this reason, it is difficult to accurately and selectively etch and remove only the ohmic contact layer while reserving only the a-Si film as a channel layer. Therefore, in a case of a large-area substrate, uniformity failure in TFT characteristics is liable to be generated due to uniformity failure in an etching (removing) process, which may result in generation of failure such as display unevenness. Therefore, stabilization of quality of TFT substrates is difficult.

In the technology of forming both of the pixel TFT and the drive TFT on the same substrate by using a microcrystalline or polycrystalline Si layer having high mobility as a channel layer as disclosed in Japanese Patent Application Laid-Open No. 5-63196 (1993), a high temperature process close to 1000° C. is necessary in order to crystallize Si. For this reason, a special device such as a high-temperature annealing furnace is required. Further, an expensive substrate having high heat resistance, such as quartz, is required, and hence there are problems of causing increase in component cost and inability to manufacture a large-size LCD due to difficulty in increasing the size of a quartz substrate. As a method of making Si polycrystalline at a comparatively low temperature other than the process using a high-temperature annealing furnace, there is a laser annealing method of irradiating Si with an excimer laser or the like. The polycrystalline Si technology with laser irradiation is widely known as a low temperature poly silicon (LTPS) technology, and generally, a processing temperature can be made 500° C. or below. In this method, however, in order to uniformly crystallize a Si channel layer that ranges over a wide area, highly accurate control is required at the time of scanning the laser in a wide range. For this reason, an expensive laser irradiation device needs to be introduced, which causes increase in manufacturing cost. Further, even in a case of using crystalline Si as described above, similarly to the case of a-Si, etching uniformity in the BCE process may be a problem.

According to the technologies of Japanese Patent Application Laid-Open No. 2011-29579 and Japanese Patent Application Laid-Open No. 2011-44699, as described above, both of the pixel TFT and the drive TFT can be stably formed on the same substrate by using an oxide semiconductor as a channel layer. Further, an amorphous oxide as an oxide semiconductor can be manufactured in a comparatively low-temperature process. For this reason, the same facility as a facility for the related-art a-Si can be used, thereby being capable of suppressing increase in manufacturing cost. However, deterioration of characteristics of a TFT that uses an oxide semiconductor as a channel layer under influence of light (light deterioration) has been pointed out (refer to Chio-Shun Chuang et al., “Photosensitivity of Amorphous IGZO TFTs for Active-Matrix Flat-Panel Displays,” SID DIGEST, 2008, pp. 1215-1218 and Dharam Pal Gosain et al., “Instability of Amorphous Indium Gallium Zinc Oxide Thin Film Transistors under Light Illumination,” Japanese Journal of Applied Physics, 2009, vol. 48, pp. 03B018-1-03B018-5, for example). The light deterioration of a drive TFT of the drive circuit, which is provided in a frame region outside a display region of the liquid crystal panel, can be easily prevented by shielding the frame region from light, for example. On the other hand, in a pixel TFT, which is arranged in the display region for controlling a pixel, light deterioration is liable to be generated due to entrance of leakage light (stray light) derived from a backlight from a rear surface side or derived from outside light from a front surface side into a channel layer. As a result, display failure may be generated.

### SUMMARY

The present invention is made in order to solve such problems as described above, and one object thereof is to provide a TFT substrate having a configuration in which both of a TFT using a-Si as a material for a channel layer and a TFT using an oxide semiconductor film are formed on a single substrate at a low cost and with stable quality. Further, another object is to provide an LCD having high resistance to light deterioration. Further, yet another object is to provide a TFT using an a-Si film as a channel layer with stable quality.

A thin film transistor substrate of the present invention includes a substrate, a first gate electrode, a second gate electrode, a gate insulation film, a first semiconductor layer, a first contact layer, a second contact layer, a second semiconductor layer, a first electrode, a second electrode, a pixel electrode, a third electrode, and a fourth electrode. The first gate electrode and the second gate electrode are provided on the substrate. The gate insulation film is provided on the first gate electrode and the second gate electrode. The first semiconductor layer is provided on the gate insulation film, is opposed to the first gate electrode with intermediation of the gate insulation film, and is formed of amorphous silicon. The first contact layer has a portion arranged on the first semiconductor layer, and is formed of an oxide semiconductor. The second contact layer has a portion arranged on the first semiconductor layer separately way from the first contact layer, and is formed of an oxide semiconductor. The second semiconductor layer is provided on the gate insulation film, is opposed to the second gate electrode with intermediation of the gate insulation film, and is formed of an oxide semiconductor. The first electrode is connected to the first contact layer. The second electrode is connected to the second contact layer. The pixel electrode is connected to the second electrode. The third electrode has a portion arranged on the second semiconductor layer. The fourth electrode has a portion arranged on the second semiconductor layer separately away from the third electrode.

A method of manufacturing a thin film transistor substrate of the present invention includes the following steps. A first conductive film is formed on a substrate. A pattern is provided to the first conductive film such that a first gate electrode and a second gate electrode are formed. A gate insulation film is formed on the first gate electrode and the second gate electrode. An amorphous silicon film is formed on the gate insulation film. A pattern is provided to the amorphous silicon film such that a first semiconductor layer opposed to the first gate electrode with intermediation of the gate insulation film is formed. An oxide semiconductor film is formed on the gate insulation film on which the first semiconductor layer is provided. A pattern is provided to the oxide semiconductor film. A second conductive film is formed on the gate insulation film on which the first semiconductor layer and the oxide semiconductor film are provided. A pattern is provided to the second conductive film. Through the steps of providing a pattern to the oxide semiconductor film and providing a pattern to the second conductive film, a first contact layer having a portion arranged on the first semiconductor layer, a second contact layer having a portion arranged on the first semiconductor layer separately away from the first contact layer, and a second semiconductor layer provided on the gate insulation film and opposed to the second gate electrode with intermediation of the gate insulation film are formed from the oxide semiconductor film, and a first electrode connected to the first contact layer, a second electrode connected to the second contact layer, a third electrode having a portion arranged on the second semiconductor layer, and a fourth electrode having a portion arranged on the second semiconductor layer separately away from the third electrode are formed from the second conductive film. A pixel electrode connected to the second electrode is formed.

A liquid crystal display of the present invention includes a thin film transistor substrate, an opposing substrate, a liquid crystal layer, and a light shielding layer. The thin film transistor substrate includes a display region in which a first transistor having a channel layer formed of amorphous silicon is provided, and a frame region in which a second transistor having a channel layer formed of an oxide semiconductor is provided. The frame region is arranged outside the display region. The opposing substrate is opposed to the thin film transistor with a gap therebetween, and has light transmitting property. The liquid crystal layer is arranged in the gap between the thin film transistor substrate and the opposing substrate. The light shielding layer is provided partially on the opposing substrate so as to be opposed to the frame region.

A thin film transistor of the present invention includes a substrate, a first gate electrode, a gate insulation film, a first semiconductor layer, a first contact layer, a second contact layer, a first electrode, and a second electrode. The first gate electrode is provided on the substrate. The gate insulation film is provided on the first gate electrode. The first semiconductor layer is provided on the gate insulation film, is opposed to the first gate electrode with intermediation of the gate insulation film, and is formed of amorphous silicon. The first contact layer has a portion arranged on the first semiconductor layer, and is formed of an oxide semiconductor. The second contact layer has a portion arranged on the first semiconductor layer separately away from the first contact layer, and is formed of an oxide semiconductor. The first electrode is connected to the first contact layer. The second electrode is connected to the second contact layer.

According to the thin film transistor or the thin film transistor substrate of the present invention, a thin film transistor using amorphous silicon as a channel layer can be obtained with stable quality.

According to the method of manufacturing a thin film transistor substrate of the present invention, a thin film transistor substrate can be manufactured at a low cost and with stable quality.

According to the liquid crystal display of the present invention, resistance of the liquid crystal display to light deterioration can be enhanced.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view schematically illustrating a configuration of a liquid crystal display according to a first preferred embodiment of the present invention from a view corresponding to the line I-I of FIG. 2.

FIG. 2 is a plan view schematically illustrating a configuration of a thin film transistor substrate of the liquid crystal display of FIG. 1.

FIG. 3 is a circuit diagram illustrating an example of a drive voltage generation circuit of a scan signal drive circuit provided in the thin film transistor substrate of FIG. 2.

FIG. 4 is a partial plan view schematically illustrating a configuration of a unit structure provided in a display region of the thin film transistor substrate of FIG. 2.

FIG. 5 is a partial cross-sectional view schematically illustrating a configuration of a transistor provided in a frame region of the thin film transistor substrate of FIG. 2.

FIG. 6 is a partial cross-sectional view taken along the line A1-A2 of FIG. 4 and the line B1-B2 of FIG. 5.

FIGS. 7 to 11 are each a partial cross-sectional view schematically illustrating a process of a manufacturing method for a thin film transistor substrate according to the first preferred embodiment of the present invention in a field of view corresponding to FIG. 6.

FIG. 12 is a partial plan view schematically illustrating a configuration of a unit structure provided in a display region of a thin film transistor substrate according to a modified example of the first preferred embodiment of the present invention in a field of view corresponding to FIG. 4.

FIG. 13 is a partial plan view schematically illustrating a configuration of a transistor provided in a frame region of the thin film transistor substrate according to the modified example of the first preferred embodiment of the present invention in a field of view corresponding to FIG. 5.

FIG. 14 is a partial cross-sectional view taken along the line A1-A2 of FIG. 12 and the line B1-B2 of FIG. 13.

FIGS. 15 to 23 are each a partial cross-sectional view schematically illustrating a process of a manufacturing method for a thin film transistor substrate according to the modified example of the first preferred embodiment of the present invention in a field of view corresponding to FIG. 14.

FIG. 24 is a partial cross-sectional view schematically illustrating a configuration of a thin film transistor substrate according to a second preferred embodiment of the present invention in a field of view similar to FIG. 6.

FIGS. 25 and 26 are each a partial cross-sectional view schematically illustrating a process of a manufacturing method for a thin film transistor substrate according to the second preferred embodiment of the present invention in a field of view corresponding to FIG. 24.

FIG. 27 is a partial plan view schematically illustrating a configuration of a unit structure provided in a display region of a thin film transistor substrate according to a third preferred embodiment of the present invention in a field of view corresponding to FIG. 4.

FIG. 28 is a partial plan view schematically illustrating a configuration of a transistor provided in a frame region of the thin film transistor substrate according to the third preferred embodiment of the present invention in a field of view corresponding to FIG. 5.

FIG. 29 is a partial cross-sectional view taken along the line A1-A2 of FIG. 27 and the line B1-B2 of FIG. 28.

FIG. 30 is a partial cross-sectional view schematically illustrating a process of a manufacturing method for a thin film transistor substrate according to the third preferred embodiment of the present invention in a field of view corresponding to FIG. 29.

### DESCRIPTION OF THE PREFERRED EMBODIMENTS

Now, preferred embodiments of the present invention are described in detail referring to the drawings. A TFT according to preferred embodiments of the present invention is used as a switching element, and is applicable to a pixel use and a drive circuit use in a TFT substrate for an LCD or the like. Note that, in the drawings below, the same or corresponding components are denoted by the same reference numbers to omit repeated description thereof.

### First Preferred Embodiment

(Configuration of LCD)

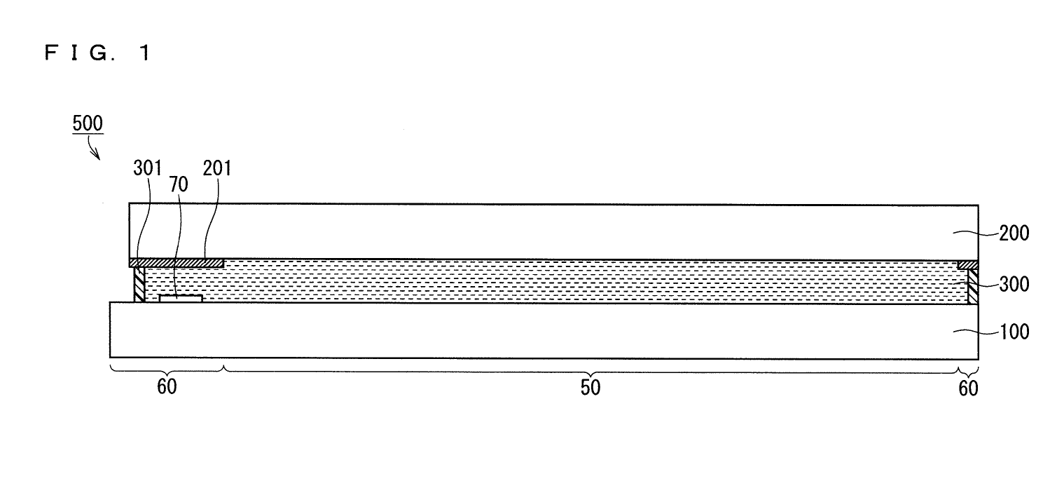

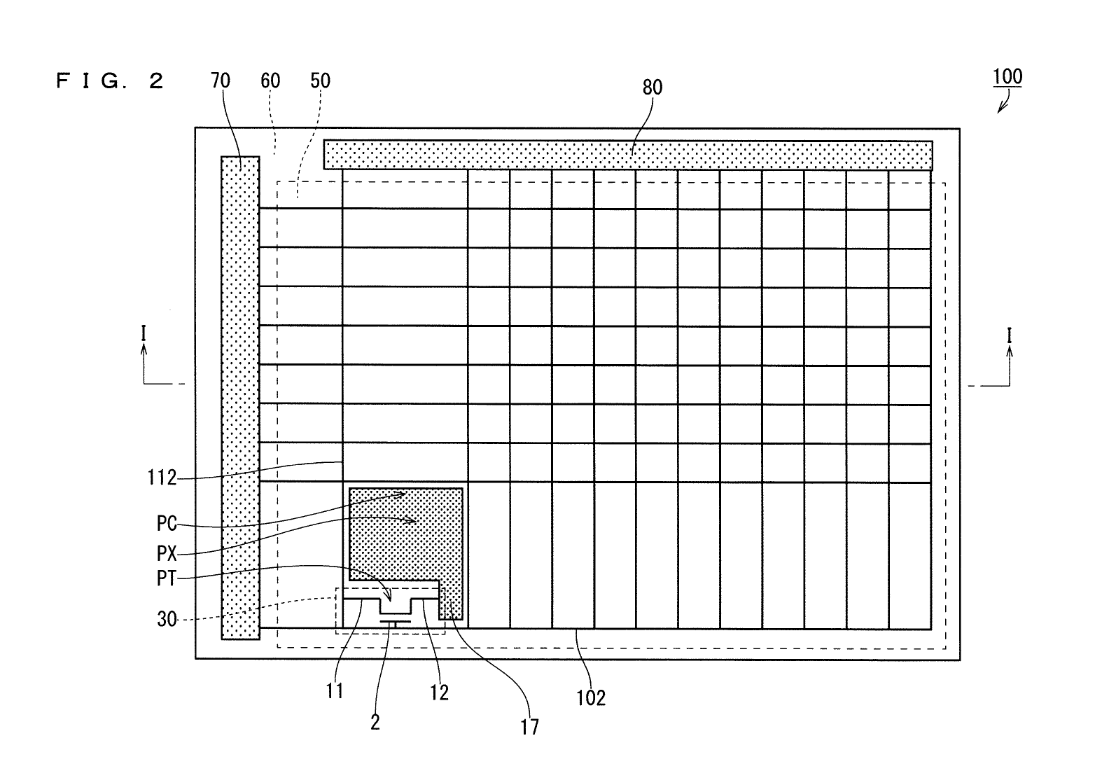

FIG. 1 is a cross-sectional view schematically illustrating an LCD 500 (liquid crystal display) according to a first preferred embodiment of the present invention, particularly a liquid crystal panel being a principal part thereof, from a view corresponding to the line I-I of FIG. 2. FIG. 2 is a plan view schematically illustrating a configuration of a TFT substrate 100 (thin film transistor substrate) of the LCD 500 of FIG. 1. The LCD 500 includes the TFT substrate 100, an opposing substrate 200, a liquid crystal layer 300, a light shielding layer 201, and a sealing member 301.

The TFT substrate 100 includes a display region 50 and a frame region 60 that is arranged outside the display region 50. Although detailed description will be given later, in the display region 50, a pixel TFT for controlling display of each of pixels of the LCD 500 is provided. Further, in the frame region 60, in order to drive the pixel TFT, a drive circuit including a scan signal drive circuit 70 is provided. The drive circuit includes a drive TFT. The pixel TFT includes a channel layer formed of a-Si. The drive TFT includes a channel layer formed of an oxide semiconductor.

The opposing substrate 200 is opposed to the TFT substrate 100 with a gap therebetween, and has light transmitting property. In order to maintain the predetermined gap, spacers (not shown) are provided between the TFT substrate 100 and the opposing substrate 200. The liquid crystal layer 300 is arranged in the above-mentioned gap between the TFT substrate 100 and the opposing substrate 200, and is sealed by the sealing member 301. Color filters may be provided on the opposing substrate 200.

Alignment films (not shown) are provided on a surface of the TFT substrate 100 to be opposed to the opposing substrate 200 and on a surface of the opposing substrate 200 to be opposed to the TFT substrate 100. The alignment film is provided for aligning liquid crystals, and is formed of polyimide or the like, for example.

The light shielding layer 201 is provided partially on the opposing substrate 200 so as to be opposed to the frame region 60. Therefore, the light shielding layer 201 has a portion opposed to the above-mentioned drive TFT in the thickness direction (vertical direction in FIG. 1). The shape of the light shielding layer 201 in a plan view may be the same as that of the frame region 60 of the TFT substrate 100. The light shielding layer 201 has a function of blocking light so as not to allow light from the periphery of the display region 50 to affect a display image of the LCD 500. Further, in this preferred embodiment, the light shielding layer 201 has a function of preventing light, such as leakage light derived from outside light from a front surface side of the LCD 500, from entering the channel layer of the drive TFT provided in the frame region 60.

Note that, the opposing substrate 200 has a black matrix (not shown) so as to be opposed to the display region of the TFT substrate 100. The black matrix may be formed together with the light shielding layer 201. In the LCD 500, a polarizing plate, a retardation plate, a backlight unit, and the like may further be provided on the outside of the liquid crystal panel having the above-mentioned structure.

(Configuration of TFT Substrate)

Firstly, the gist of a configuration of the TFT substrate 100 is described below. Note that, in this preferred embodiment, description is given assuming that the TFT substrate 100 is used for an LCD of a vertical electric field driving mode as typified by a light transmitting TN mode or VA mode.

The TFT substrate 100 (FIG. 2) includes, as described above, the display region 50 and the frame region 60 that is arranged outside the display region 50.

The display region 50 includes a plurality of pixels arranged in a matrix pattern. Each pixel has a pixel region PX and a pixel transistor region PT. The pixel TFT 30 (first transistor) is provided in the pixel transistor region PT. A channel layer of the pixel TFT 30 is, as in the description given later, formed of a-Si, which is a semiconductor having high resistance to light deterioration. With this, quality and reliability of display can be enhanced. In the display region 50, a plurality of gate wires 102 and a plurality of source wires 112 are arranged so as to intersect with each other, and are typically arranged so as to be orthogonal to each other. The above-mentioned arrangement of the matrix pattern corresponds to arrangement of intersecting portions of the gate wires 102 and the source wires 112.

In the frame region 60, a drive circuit for driving the pixel TFT 30 is provided. The drive circuit is provided on a substrate 1 of the TFT substrate 100 not through mounting of an external IC but through a semiconductor processing technology such as deposition and patterning. With this, the area of the frame region 60 can be reduced. In view of the performance required for a TFT to be used in a drive circuit, a channel layer thereof needs to have high mobility, and is therefore formed of an oxide semiconductor in this preferred embodiment. The drive circuit includes a display signal drive circuit 80 in addition to the above-mentioned scan signal drive circuit 70. The scan signal drive circuit 70 applies a drive voltage to the gate wires 102. The display signal drive circuit 80 applies a drive voltage to the source wires 112. The pixel TFT 30 provided in a pixel present at an intersection of one gate wire to which an electric current is selectively applied by the scan signal drive circuit 70 and one source wire to which an electric current is selectively applied by the display signal drive circuit 80 is brought into the on state, and receives supply of a source electric current. As a result, an electric charge is stored in a pixel electrode 17 connected to the pixel TFT 30.

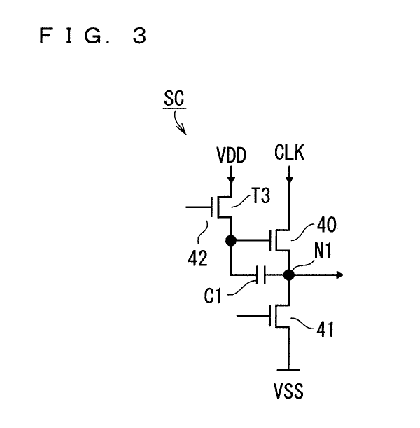

FIG. 3 is a circuit diagram illustrating an example of each of a plurality of drive voltage generation circuits SC of the scan signal drive circuit 70. The drive voltage generation circuit SC includes drive TFTs 40 to 42 (second transistors). The display signal drive circuit 80 also has a similar configuration. Here, an electric current of the drive TFTs is assumed to flow from a drain electrode to a source electrode. In the drive TFT 40, a clock signal CLK is applied to a drain. In the drive TFT 41, a ground potential VSS is applied to a source, and a drain is connected to a source of the drive TFT 40. In the drive TFT 42, a power supply potential VDD is applied to a drain, and a gate of the drive TFT 40 is connected to a source. The source of the drive TFT 42 is connected to a connection node N1 between the drive TFT 40 and the drive TFT 41 via a capacitor C1. The connection node N1 functions as an output node of the drive voltage generation circuit SC, and applies a drive voltage to a corresponding gate wire 102 or source wire 112. Specifically, the drive TFT 42 is turned on by a signal applied to a gate of the drive TFT 42, thereby bringing the drive TFT 40 into the on state. With this, the clock signal CLK is output from the connection node N1. Further, the drive TFT 41 is turned on by a signal applied to a gate of the drive TFT 41, thereby fixing a potential of the connection node N1 to be the ground potential VSS.

In this preferred embodiment, as described above, a-Si, which is a semiconductor having high resistance to light deterioration, is used for a channel layer of the pixel TFT 30. With this, the LCD 500 having stabile display characteristics can be obtained. Further, an oxide semiconductor, which is a semiconductor having high mobility, is used for channel layers of the drive TFTs 40 to 42. With this, the scan signal drive circuit 70 and the display signal drive circuit 80 that are capable of stable operation can be obtained. Further, the areas of the scan signal drive circuit 70 and the display signal drive circuit 80 can be reduced. Therefore, the manufacturing cost of the scan signal drive circuit 70 and the display signal drive circuit 80 can be suppressed, and the LCD 500 having a narrow frame can be manufactured through reduction of the area of the frame region 60.

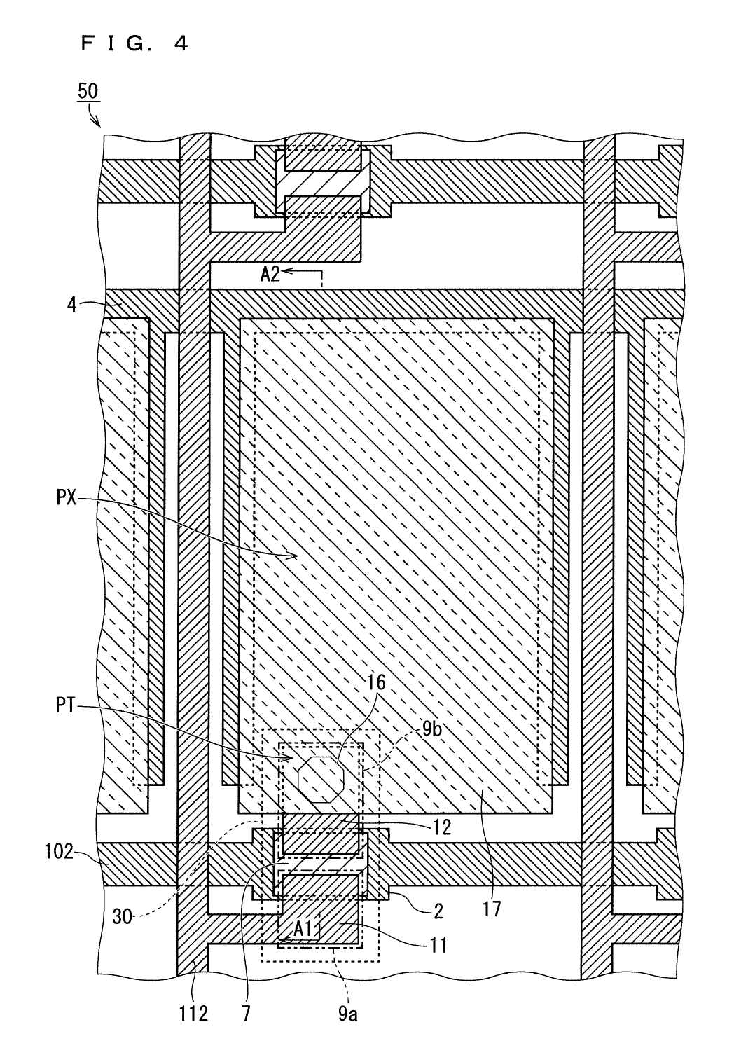

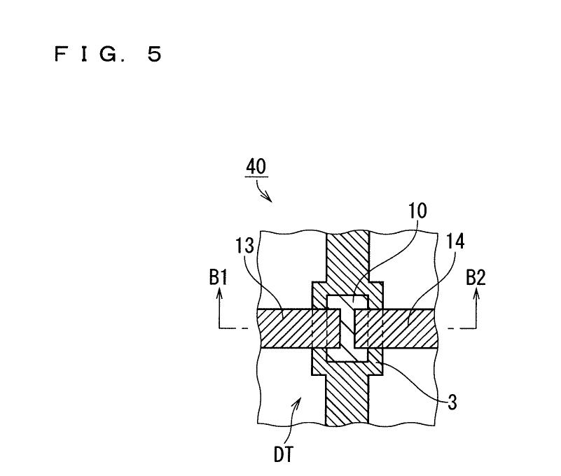

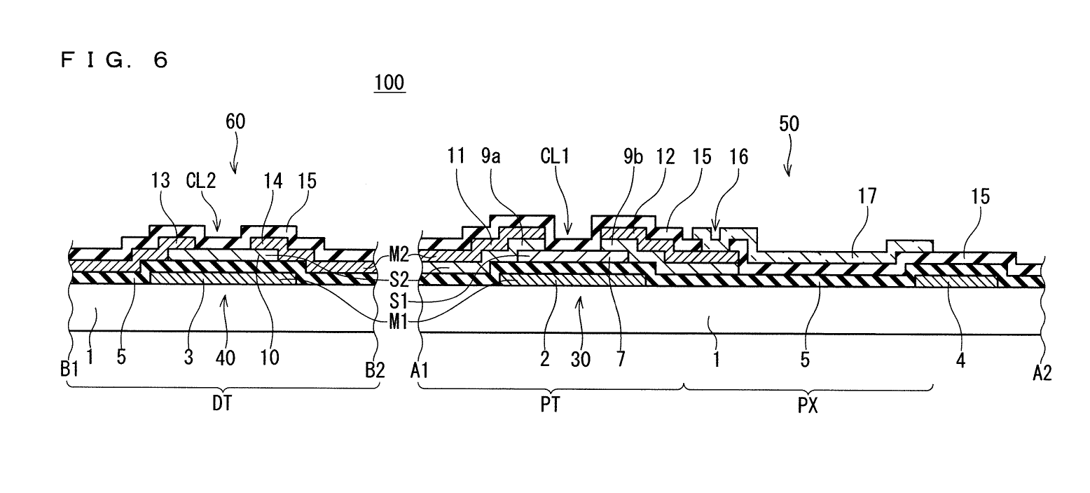

Next, a detailed configuration of the TFT substrate 100 is described below. FIG. 4 is a partial plan view schematically illustrating a configuration of a unit structure provided in the display region 50 of the TFT substrate 100 (FIG. 2). The pixel TFT 30 is provided in each unit structure. FIG. 5 is a partial cross-sectional view schematically illustrating a configuration of the drive TFT 40 provided in a drive transistor region DT included in the frame region 60 of the TFT substrate 100. The configuration of the drive TFTs 41 and 42 (FIG. 3) is substantially the same as that of the drive TFT 40, and therefore description thereof is omitted. FIG. 6 is a partial cross-sectional view taken along the line A1-A2 (FIG. 4) and the line B1-B2 (FIG. 5). Note that, in the plan views of FIG. 4 and FIG. 5, for the sake of simplifying the drawings, a configuration formed of an insulator is not shown, and hatching is employed.

The TFT substrate 100 includes the substrate 1 and a stacking structure on the substrate 1. The stacking structure includes, on the substrate 1, a first conductive film M1, a gate insulation film 5, an amorphous silicon film S1, an oxide semiconductor film S2, a second conductive film M2, the pixel electrode 17, and a protective insulation film 15 in the order as mentioned.

The substrate 1 is an insulating substrate. In this preferred embodiment, the substrate 1 has light transmitting property, and is preferably a transparent substrate. For example, the substrate 1 is a glass substrate.

The first conductive film M1 includes a first gate electrode 2, a second gate electrode 3, and a common electrode 4, as its pattern. Therefore, the first gate electrode 2, the second gate electrode 3, and the common electrode 4 are formed of a conductor, and are typically formed of a common conductor. It is preferable that the conductor be formed of metal, and the “metal” herein may be an alloy. Typically, the first gate electrode 2, the second gate electrode 3, and the common electrode 4 are formed of the same material. The first conductive film M1 has light shielding property. The first conductive film M1 is provided directly on the substrate 1. Therefore, each of the first gate electrode 2, the second gate electrode 3, and the common electrode 4 is provided directly on the substrate 1. The first gate electrode 2 is formed in a region where the pixel TFT 30 is to be formed, and functions as a gate electrode of the pixel TFT 30. The second gate electrode 3 is formed in a region where the drive TFT 40 is to be formed, and functions as a gate electrode of the drive TFT 40. The common electrode 4 is provided on the substrate 1 separately away from the first gate electrode 2 and the second gate electrode 3.

The gate insulation film 5 is provided on the first gate electrode 2 and the second gate electrode 3. Specifically, the gate insulation film 5 is formed on the entire substrate 1 so as to cover the first gate electrode 2, the second gate electrode 3, and the like. The gate insulation film 5 is an insulation film having a part functioning as a gate insulation film for each of the first gate electrode 2 and the second gate electrode 3, and as in the illustration, may further have a part other than the above-mentioned part.

The amorphous silicon film Si includes a first semiconductor layer 7 as its pattern. Therefore, the first semiconductor layer 7 is formed of amorphous silicon.

The oxide semiconductor film S2 includes a source contact layer 9a (first contact layer), a drain contact layer 9b (second contact layer), and a second semiconductor layer 10, as its pattern. Therefore, the source contact layer 9a, the drain contact layer 9b, and the second semiconductor layer 10 are formed of an oxide semiconductor. The source contact layer 9a, the drain contact layer 9b, and the second semiconductor layer 10 preferably contain at least one metallic element species in common, more preferably are formed of a metallic oxide of the same type, and still more preferably are formed of substantially the same material. The “metallic oxide of the same type” herein means an oxide containing all metallic element species in common.

The first semiconductor layer 7 as a pattern of the amorphous silicon film S1 is provided on the gate insulation film 5, and is opposed to the first gate electrode 2 with intermediation of the gate insulation film 5. With this, the first semiconductor layer 7 is included in the pixel TFT 30, thus functioning as a channel layer thereof. The second semiconductor layer 10 as a pattern of the oxide semiconductor film S2 is provided on the gate insulation film 5, and is opposed to the second gate electrode 3 with intermediation of the gate insulation film 5. With this, the second semiconductor layer 10 is included in the drive TFT 40, thus functioning as a channel layer thereof. The second semiconductor layer 10 may be arranged directly on the gate insulation film 5. In a plan view (as viewed from the top), on the gate insulation film 5, the first semiconductor layer 7 of the amorphous silicon film Si is formed in a part of a region overlapping the first gate electrode 2, and the second semiconductor layer 10 of the oxide semiconductor film S2 is formed in a part of a region overlapping the second gate electrode 3.

Each of the source contact layer 9a and the drain contact layer 9b has a part arranged on the first semiconductor layer 7. The source contact layer 9a and the drain contact layer 9b are separated away from each other on the first semiconductor layer 7. In a plan view, of the first semiconductor layer 7, a portion between the source contact layer 9a and the drain contact layer 9b has a function as a channel region (back channel region) CL1.

The second conductive film M2 includes a first source electrode 11 (first electrode), a first drain electrode 12 (second electrode), a second source electrode 13 (third electrode), and a second drain electrode 14 (fourth electrode), as its pattern. Therefore, the first source electrode 11, the first drain electrode 12, the second source electrode 13, and the second drain electrode 14 are formed of a conductor, and are preferably formed of metal. Note that, the “metal” may be an alloy. Typically, the first source electrode 11, the first drain electrode 12, the second source electrode 13, and the second drain electrode 14 are formed of the same material. The second conductive film M2 has light shielding property.

In a plan view, the first source electrode 11 is formed so as to overlap a part of a region of the source contact layer 9a, and the first drain electrode 12 is formed so as to overlap a part of a region of the drain contact layer 9b. Further, the second source electrode 13 and the second drain electrode 14 are formed so as to overlap a part of a region of the second semiconductor layer 10, and are arranged separately away from each other on the second semiconductor layer 10. Of the second semiconductor layer 10, a portion between the second source electrode 13 and the second drain electrode 14 has a function as a channel region (back channel region) CL2.

The first source electrode 11 is connected to the source contact layer 9a. With this, the first source electrode 11 is electrically connected to the first semiconductor layer 7 via the source contact layer 9a. Similarly, the first drain electrode 12 is connected to the drain contact layer 9b. With this, the first drain electrode 12 is electrically connected to the first semiconductor layer 7 via the drain contact layer 9b. The first source electrode 11 and the first drain electrode 12 are ohmically connected to the first semiconductor layer 7 via the source contact layer 9a and the drain contact layer 9b, respectively. That is, the source contact layer 9a and the drain contact layer 9b have a function as an ohmic contact layer. In view of attaining such a function sufficiently, it is preferable that the source contact layer 9a and the drain contact layer 9b be formed of an n-type semiconductor having electron carrier density of 1×10¹² cm⁻³ or more and 1×10¹⁹ cm⁻³ or less.

The second source electrode 13 has a portion arranged on the second semiconductor layer 10. The second drain electrode 14 has a portion arranged on the second semiconductor layer 10 separately away from the second source electrode 13. Each of the second source electrode 13 and the second drain electrode 14 is, as illustrated in FIG. 6, directly connected to the second semiconductor layer 10. The second semiconductor layer 10 is formed of an oxide semiconductor unlike the first semiconductor layer 7, and therefore satisfactory electrical connection with the second source electrode 13 and the second drain electrode 14 can be obtained without an ohmic contact layer.

The protective insulation film 15 is provided on the substrate 1 on which a stacking structure up to the second conductive film M2 is provided. In the protective insulation film 15, a contact hole 16 reaching the first drain electrode 12 is provided. The contact hole 16 is, in a plan view, an opening provided in the protective insulation film 15 so as to expose a part of a surface of the first drain electrode 12.

The pixel electrode 17 is formed of a transparent conductive film. The pixel electrode 17 is provided on the protective insulation film 15, and is connected to the first drain electrode 12 through the contact hole 16. The pixel electrode 17 is, in a plan view (FIG. 4), arranged in the pixel region PX. In a plan view (FIG. 4), the pixel electrode 17 has a portion overlapping the common electrode 4, and in a cross-sectional view (FIG. 6), the pixel electrode 17 is isolated from the common electrode 4 by the gate insulation film 5 and the protective insulation film 15. With this, a holding capacitance is provided in the pixel electrode 17.

(Configuration of Pixel TFT)

Although the above description is partly repeated, placing a focus particularly on the pixel TFT 30 (thin film transistor), a structure thereof is described below. The pixel TFT 30 includes the substrate 1, the first gate electrode 2, the gate insulation film 5, the first semiconductor layer 7, the source contact layer 9a, the drain contact layer 9b, the first source electrode 11, and the first drain electrode 12. The first gate electrode 2 is provided on the substrate 1. The gate insulation film 5 is provided on the first gate electrode 2. The first semiconductor layer 7 is provided on the gate insulation film 5, is opposed to the first gate electrode 2 with intermediation of the gate insulation film 5, and is formed of a-Si. The source contact layer 9a has a portion arranged on the first semiconductor layer 7, and is formed of an oxide semiconductor. The drain contact layer 9b has a portion arranged on the first semiconductor layer 7 separately away from the source contact layer 9a, and is formed of an oxide semiconductor. The first source electrode 11 is connected to the source contact layer 9a. The first drain electrode 12 is connected to the drain contact layer 9b.

(Manufacturing Method for TFT Substrate)

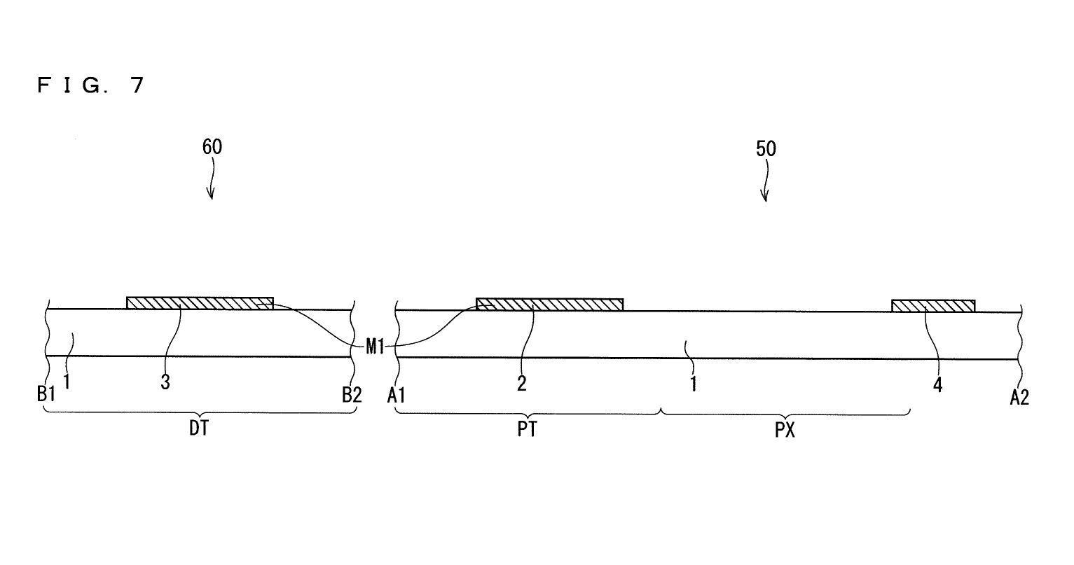

FIG. 7 to FIG. 11 are partial cross-sectional views schematically illustrating a manufacturing method for the TFT substrate 100 in a field of view corresponding to FIG. 6 in order of processes.

Referring to FIG. 7, firstly, the substrate 1, which is a transparent insulating substrate such as a glass substrate, is prepared. Next, the substrate 1 is cleaned using a cleaning liquid or pure water. Next, the first conductive film M1 is formed on an entire main surface of the substrate 1 on one side (upper surface in the drawing). A material for the first conductive film M1 may be metal such as chromium (Cr), molybdenum (Mo), titanium (Ti), copper (Cu), tantalum (Ta), tungsten (W), and aluminum (Al), or may be an alloy containing those metallic elements as a main component and one or more types of other elements being added thereto. An element of a main component herein means a most contained element among elements forming the alloy. Further, the first conductive film M1 may have a stacking structure including two or more layers of those metal layers or alloy layers. Using those metals or alloys, a conductive film having a specific resistance value of 50 μΩcm or less can be obtained. For example, on the substrate 1 having a thickness 0.6 mm, a Cu film having a thickness of 200 nm is formed as the first conductive film M1 with a sputtering method using an argon (Ar) gas.

Next, a pattern is provided to the first conductive film M1 such that the first gate electrode 2, the second gate electrode 3, and the common electrode 4 are formed. Specifically, a photoresist material is applied on the first conductive film M1 to form a photoresist pattern in a first photolithographic process, and the first conductive film M1 is patterned through etching using the photoresist pattern as a mask. This etching is performed, for example, by wet etching using an ammonium peroxodisulfate-based solution. The ammonium peroxodisulfate-based solution is, for example, prepared using an ammonium peroxodisulfate solution having concentration of 0.3 wt %. After that, the photoresist pattern is removed, thereby obtaining a structure illustrated in FIG. 7.

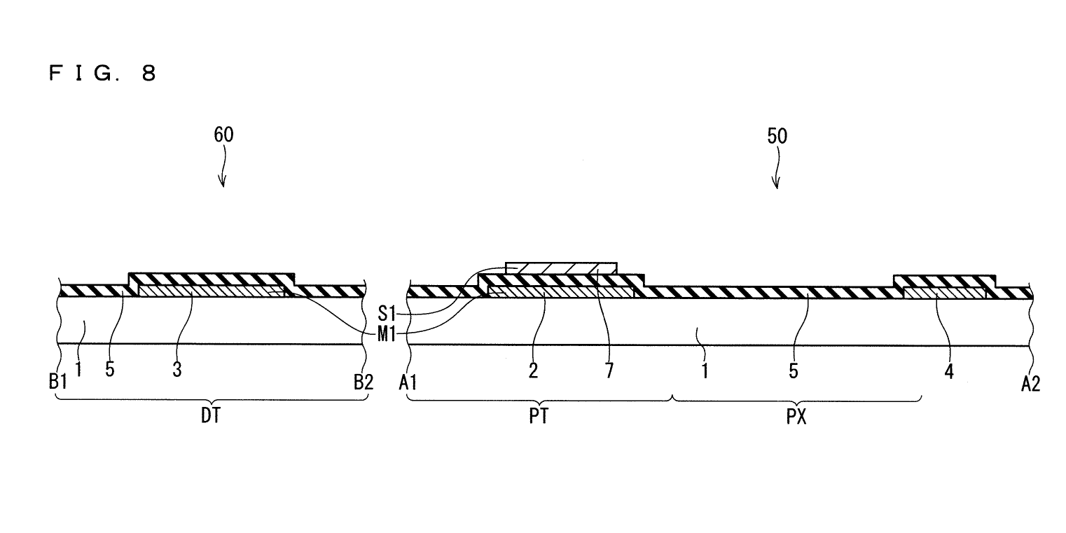

Referring to FIG. 8, the gate insulation film 5 is formed on the first gate electrode 2, the second gate electrode 3, and the common electrode 4. For example, a silicon nitride (SiN) film having a thickness of 400 nm is formed using a chemical vapor deposition (CVD) method.

Next, the amorphous silicon film Si is formed on the gate insulation film 5. For example, the amorphous silicon film S1 having a thickness of 100 nm is formed with the CVD method.

Next, a pattern is provided to the amorphous silicon film Si such that the first semiconductor layer 7 opposed to the first gate electrode 2 with intermediation of the gate insulation film 5 is formed. In other words, a photoresist pattern is formed in a second photolithographic process, and the amorphous silicon film Si is patterned through etching using the photoresist pattern as a mask. This etching is performed, for example, by dry etching using an etching gas containing a sulfur hexafluoride (SF₆) gas, which is a gas containing fluorine atoms, and a hydrogen chloride (HCl) gas. After that, the photoresist pattern is removed, thereby obtaining a structure illustrated in FIG. 8.

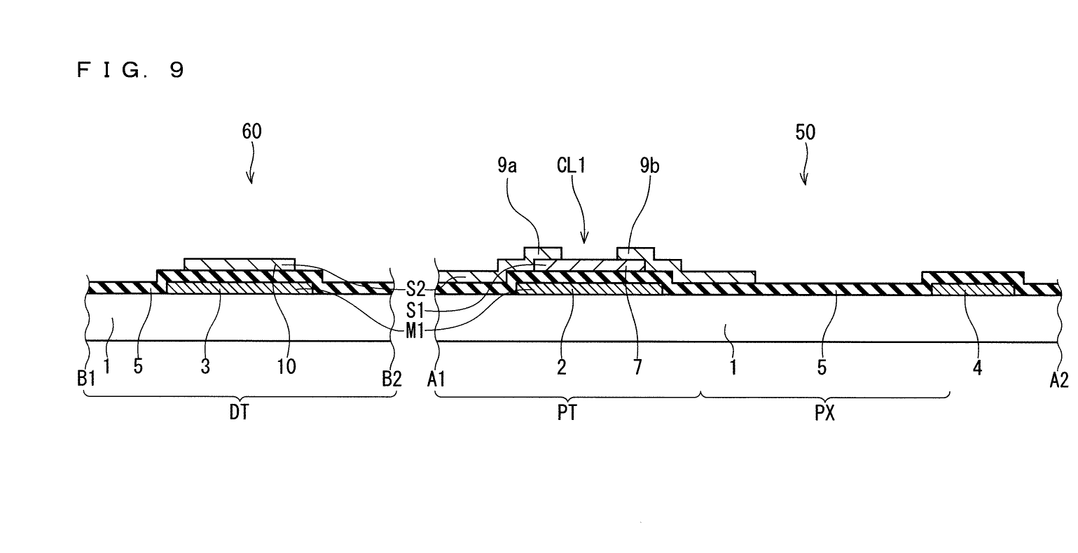

Referring to FIG. 9, the oxide semiconductor film S2 is formed on the gate insulation film 5 on which the first semiconductor layer 7 has been provided. As a material for the oxide semiconductor film S2, an oxide containing In, Ga, and Zn (such as InGaZnO) may be used. For example, with a sputtering method using an InGaZnO target having an atomic composition ratio of In:Ga:Zn:O=1:1:1:4 (that is, composition of In₂O₃.Ga₂O₃.2 (ZnO)), an InGaZnO film having a thickness of 50 nm is formed. Note that, the InGaZnO film is an n-type semiconductor having electron carriers.

Next, through the process of providing a pattern to the oxide semiconductor film S2, the source contact layer 9a having a portion arranged on the first semiconductor layer 7, the drain contact layer 9b having a portion arranged on the first semiconductor layer 7 separately away from the source contact layer 9a, and the second semiconductor layer 10 provided on the gate insulation film 5 and opposed to the second gate electrode 3 with intermediation of the gate insulation film 5 are formed of the oxide semiconductor film S2. Of the first semiconductor layer 7, a portion exposed between the source contact layer 9a and the drain contact layer 9b in a plan view becomes the channel region CL1. Specifically, a photoresist pattern is formed in a third photolithographic process, and the oxide semiconductor film S2 is patterned through etching using the photoresist pattern as a mask. For example, etching of the InGaZnO film as the oxide semiconductor film S2 is performed by wet etching using an oxalic acid (dicarboxylic acid) solution having concentration of 5 wt %. The acidity of the oxalic acid solution is comparatively low, and hence an etchant of a usual oxalic acid-based solution etches the oxide semiconductor film S2 but does not etch the amorphous silicon film S1. With this, sufficient etching selectivity is secured. Therefore, even in a case where etching unevenness is liable to be generated due to a large-size substrate 1, the channel region CL1 can be formed with high uniformity. After that, the photoresist pattern is removed, thereby obtaining a structure illustrated in FIG. 9.

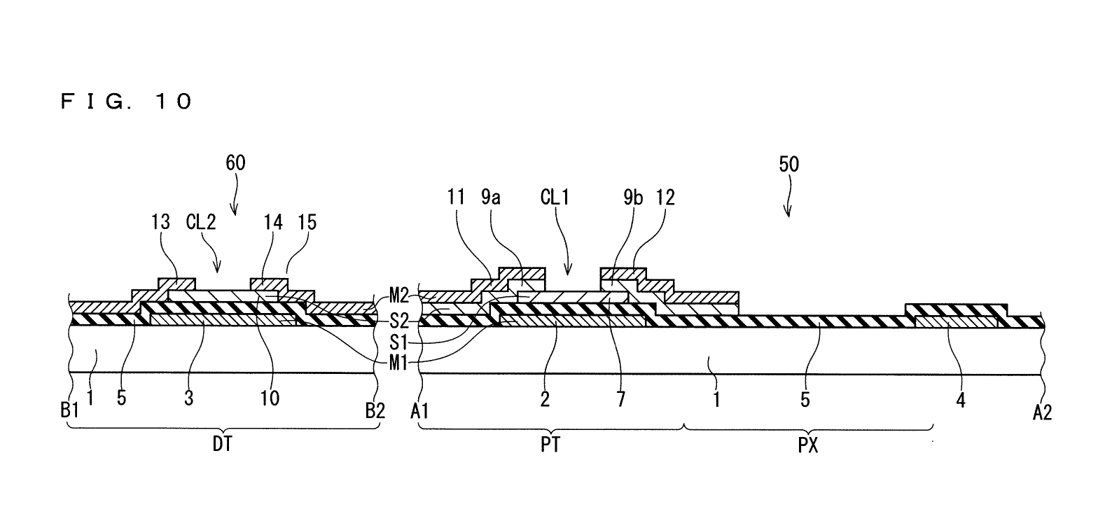

Referring to FIG. 10, the second conductive film M2 is formed on the gate insulation film 5 on which the first semiconductor layer 7 and the oxide semiconductor film S2 have been provided. For example, a Cu film having a thickness of 200 nm is formed with a sputtering method using an Ar gas.

Next, through the process of providing a pattern to the second conductive film M2, the first source electrode 11 connected to the source contact layer 9a, the first drain electrode 12 connected to the drain contact layer 9b, the second source electrode 13 having a portion arranged on the second semiconductor layer 10, and the second drain electrode 14 having a portion arranged on the second semiconductor layer 10 separately away from the second source electrode 13 are formed of the second conductive film M2. Of the second semiconductor layer 10, a portion exposed between the second source electrode 13 and the second drain electrode 14 in a plan view becomes the channel region CL2. Specifically, a photoresist pattern is formed in a fourth photolithographic process, and the second conductive film M2 is patterned through etching using the photoresist pattern as a mask. This etching is performed, for example, similarly to the etching of the first conductive film M1, by wet etching using an ammonium peroxodisulfate-based solution. After that, the photoresist pattern is removed, thereby obtaining a structure illustrated in FIG. 10.

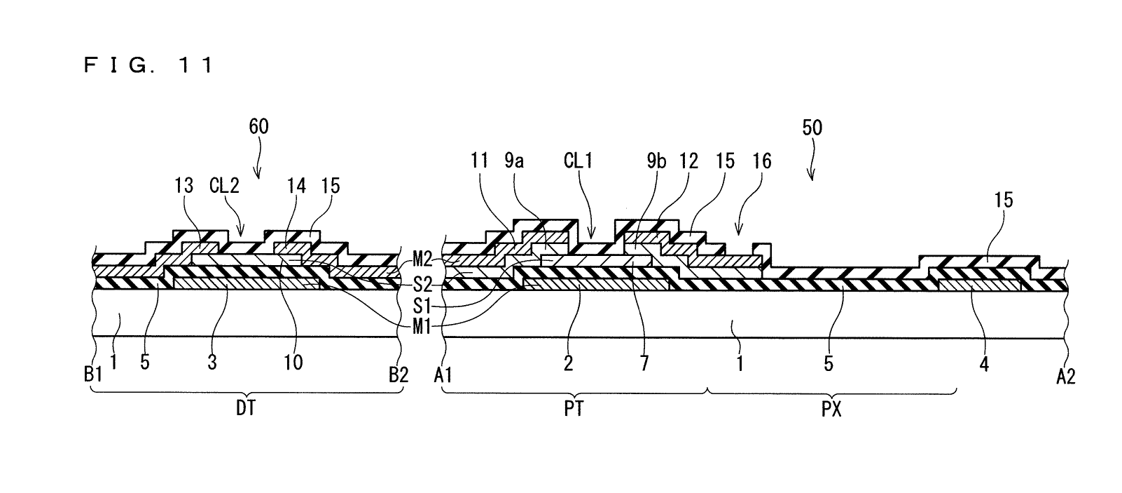

Referring to FIG. 11, on the substrate 1 on which a stacking structure up to the patterned second conductive film M2 has been provided, deposition of an insulation film and patterning thereof are performed. With this, the protective insulation film 15 having the contact hole 16 is formed. For example, a SiO film having a thickness of 100 nm and a SiN film having a thickness of 200 nm are formed with the CVD method in the order as mentioned, and subsequently, those stacked films are patterned.

Specifically, a photoresist pattern is formed in a fifth photolithographic process, and the stacked films of the SiO film and the SiN film are patterned through etching using the photoresist pattern as a mask. This etching is performed, for example, by dry etching using an etching gas obtained by adding oxygen (O₂) to sulfur hexafluoride (SF₆). After that, the photoresist pattern is removed, thereby obtaining a structure illustrated in FIG. 11.

Referring to FIG. 6 again, on the substrate 1 on which the protective insulation film 15 having the contact hole 16 has been provided, deposition of a conductive film and patterning thereof are performed. With this, the pixel electrode 17 connected to the first drain electrode 12 is formed.

Specifically, an ITO film, which is a light-transmitting oxide-based conductive film, is formed. The ITO film is a mixed oxide film of an indium oxide (In₂O₃) and a tin oxide (SnO₂), and a mixing ratio thereof is, for example, In₂O₃:SnO₂=90:10 (wt %). The ITO film is generally stable in its crystalline (polycrystalline) structure at a normal temperature. However, deposition may be performed in an amorphous state. For example, an amorphous ITO film having a thickness of 100 nm is formed with a sputtering method using, as a process gas, a mixed gas of an Ar gas and a gas containing hydrogen atoms (such as a hydrogen (H₂) gas and water vapor (H₂O)). After that, a photoresist pattern is formed in a sixth photolithographic process, and the amorphous ITO film is patterned through etching using the photoresist pattern as a mask. This etching is performed, for example, by wet etching using a solution containing an oxalic acid. After that, the photoresist pattern is removed, thereby obtaining a structure illustrated in FIG. 6. That is, the pixel electrode 17 having light transmitting property is formed in the pixel region PX. The pixel electrode 17 is directly connected to the first drain electrode 12 through the contact hole 16.

As described above, through the total of six photolithographic processes on the substrate 1, the TFT substrate 100, which includes the pixel TFT 30 having the amorphous silicon film Si as a channel layer and includes the drive TFT 40 having the oxide semiconductor film S2 as a channel layer, can be manufactured.

Note that, stacked films of a SiO film and a SiN film are formed as the protective insulation film 15 in the above-mentioned manufacturing method. However, the material for the protective insulation film 15 is not to be limited thereto. For example, a single layer film of a SiN film, a SiO film, or a SiON film may be formed, or stacked films having two layers or more, which include a SiN film and a SiO film, may be formed.

(Manufacturing Method for LCD)

Referring to FIG. 1, an alignment film and spacers (not shown) are formed on a surface of the TFT substrate 100. Next, the opposing substrate 200 including color filters, an alignment film, and the like, which is manufactured separately, is attached to the TFT substrate 100 so as to be opposed thereto. At this time, a gap is formed between the TFT substrate and the opposing substrate by the spacers (not shown). Liquid crystals are sealed in the gap using the sealing member 301. With this, a liquid crystal display panel is manufactured. Finally, a polarizing plate, a retardation plate, a backlight unit, and the like (not shown) are arranged on the outside of the liquid crystal display panel. With this, the LCD 500 is completed.

### Summary of Effects

According to the TFT substrate 100 (FIG. 6) of this preferred embodiment, firstly, the first semiconductor layer 7 as a channel layer formed of a-Si, the source contact layer 9a and the drain contact layer 9b formed of the oxide semiconductor, and the first source electrode 11 and the first drain electrode 12 respectively connected to the source contact layer 9a and the drain contact layer 9b are provided in the pixel TFT 30. A ratio of an etching rate of the oxide semiconductor being a material for the source contact layer 9a and the drain contact layer 9b to an etching rate of a-Si being a material for the first semiconductor layer 7 as a channel layer can be easily raised. With this, patterning of a contact layer on a channel layer, that is, the BCE process (FIG. 9), can be easily performed with high uniformity. With this, uniformity of characteristics of the pixel TFT 30 is enhanced, and quality of the TFT substrate 100 is stabilized. Therefore, uniformity of display of the LCD 500 (FIG. 1) using the TFT substrate 100 is enhanced, and quality thereof is stabilized.

Secondly, in the TFT substrate 100, in addition to the pixel TFT 30, another transistor having the second semiconductor layer 10 as a channel layer is further provided. The second semiconductor layer 10 is formed of an oxide semiconductor similarly to the source contact layer 9a and the drain contact layer 9b. With this, a process for forming the second semiconductor layer 10, and the source contact layer 9a and the drain contact layer 9b is simplified. Therefore, the TFT substrate 100 can be manufactured at a low cost. Further, the transistor uses, as a material for a channel layer thereof, an oxide semiconductor having high mobility compared to mobility of amorphous silicon, and hence has high performance. Therefore, the transistor may be used as a TFT for driving the pixel TFT 30, that is, as the drive TFT 40. Therefore, both of the pixel TFT 30 and the drive TFT 40 can be formed on the substrate 1 of the TFT substrate 100.

From the above, the TFT substrate 100 having a configuration in which both of the pixel TFT 30 and the drive TFT 40 are formed on a single substrate 1 can be obtained at a low cost and with stable quality.

The pixel TFT 30 is arranged in the display region 50, and hence it is difficult to completely avoid light from entering the pixel TFT 30. According to this preferred embodiment, the first semiconductor layer 7 as a channel layer of the pixel TFT 30 is formed of a-Si, which is a semiconductor having high resistance to light deterioration. Therefore, deterioration of the pixel TFT 30 caused by light deterioration can be prevented.

The source contact layer 9a, the drain contact layer 9b, and the second semiconductor layer 10 contain at least one metallic element species in common. With this, those layers can be formed by patterning a single oxide semiconductor film S2 that is formed of an oxide of such a metallic element. Therefore, a manufacturing cost of the TFT substrate 100 can further be reduced. Note that, each composition of a plurality of patterns formed of a single oxide semiconductor film S2 may be intentionally or unintentionally subjected to slight changes under influence of processes after the deposition of the oxide semiconductor film S2. However, as described above, at least one metallic element species is contained in common at the least. Further, such changes are often related to non-metallic elements such as oxygen and hydrogen, and in this case, each pattern is formed of a metallic oxide of the same type. Further, when such changes are sufficiently small, it can be said that each pattern is formed of substantially the same material.

The second semiconductor layer 10 is arranged directly on the gate insulation film 5. With this, the second semiconductor layer 10 as a channel layer is arranged adjacently to a gate electrode structure. Therefore, performance of a transistor using the second semiconductor layer 10 as a channel layer can be enhanced.

The first source electrode 11 and the first drain electrode 12 are ohmically connected to the first semiconductor layer 7 via the source contact layer 9a and the drain contact layer 9b, respectively. With this, the first source electrode 11 and the first drain electrode 12 can be electrically connected to the first semiconductor layer 7 satisfactorily. Specifically, the source contact layer 9a and the drain contact layer 9b are formed of an n-type semiconductor having electron carrier density of 1×10¹² cm⁻³ or more and 1×10¹⁹ cm⁻³ or less. With this, the first source electrode 11 and the first drain electrode 12 can be ohmically connected to the first semiconductor layer 7 via the source contact layer 9a and the drain contact layer 9b, respectively.

According to the manufacturing method for the TFT substrate 100 (FIG. 6) of this preferred embodiment, firstly, a structure as the pixel TFT 30 is formed; the structure has the first semiconductor layer 7 as a channel layer formed of a-Si, the source contact layer 9a and the drain contact layer 9b formed of an oxide semiconductor, and the first source electrode 11 and the first drain electrode 12 respectively connected to the source contact layer 9a and the drain contact layer 9b. A ratio of an etching rate of the oxide semiconductor being a material for the source contact layer 9a and the drain contact layer 9b to an etching rate of a-Si being a material for the channel layer of the pixel TFT 30 can be easily raised. With this, patterning of the source contact layer 9a and the drain contact layer 9b on a channel layer, that is, the BCE process (FIG. 9), can be easily performed with high uniformity. Therefore, uniformity of characteristics of the pixel TFT 30 is enhanced. Therefore, quality of the TFT substrate 100 is stabilized.

Secondly, in the TFT substrate 100, in addition to the pixel TFT 30, another transistor having the second semiconductor layer 10 as a channel layer is further provided. The second semiconductor layer 10, the source contact layer 9a and the drain contact layer 9b are formed collectively by providing a pattern to the oxide semiconductor film S2. With this, a process for forming the second semiconductor layer 10, the source contact layer 9a and the drain contact layer 9b is simplified. Therefore, the TFT substrate 100 can be manufactured at a low cost. Further, the above-mentioned another transistor uses, as a material for a channel layer thereof, an oxide semiconductor having high mobility compared to mobility of a-Si, and hence has high performance. Therefore, the transistor can be used as a transistor for driving the pixel TFT 30, that is, as the drive TFT 40. Therefore, both of the pixel TFT 30 and the drive TFT 40 can be formed on the substrate 1 of the TFT substrate 100.

From the above, the TFT substrate 100 having a configuration in which both of the pixel TFT 30 and the drive TFT 40 are formed on a single substrate 1 can be manufactured at a low cost and with stable quality.

The LCD 500 (FIG. 1) of this preferred embodiment includes the TFT substrate 100 having, in the frame region 60 (FIG. 2), the drive TFT 40 (FIG. 5) having a channel layer formed of an oxide semiconductor. With this, an external component having a drive TFT need not be mounted on the TFT substrate 100. Therefore, the TFT substrate 100 can be reduced in size while maintaining the size of the display region 50. Further, the channel layer of the pixel TFT 30 is formed of a-Si, and hence has high resistance to light deterioration. Further, light deterioration of the drive TFT 40 is prevented by the light shielding layer 201 provided on the opposing substrate 200. From the above, the LCD 500 having high resistance to light deterioration can be reduced in size.

### Modified Example of First Preferred Embodiment

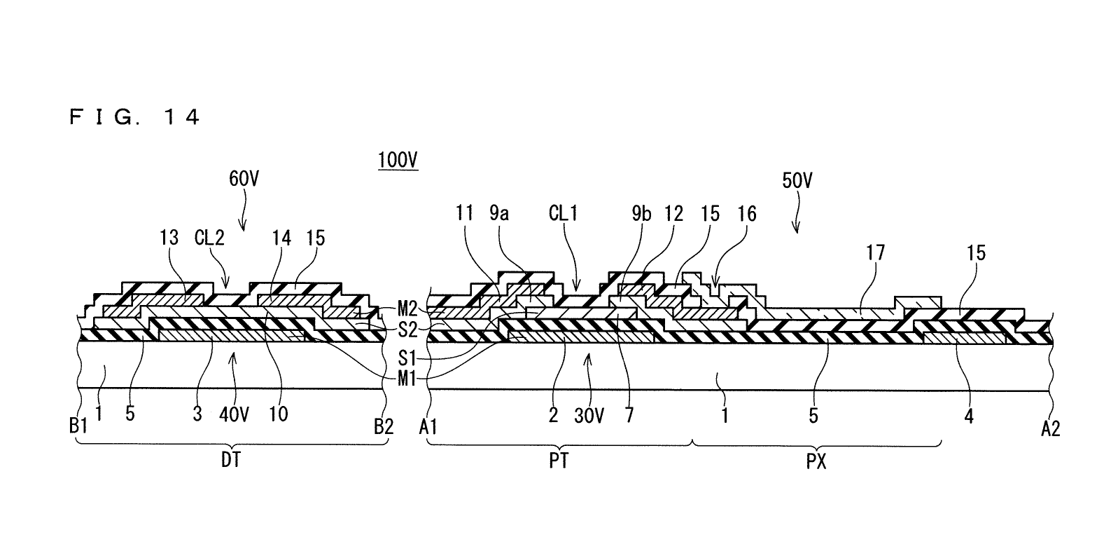

The TFT substrate 100 of the first preferred embodiment above can be manufactured through the total of six photolithographic processes. However, this modified example provides a TFT substrate 100V (thin film transistor substrate) (FIG. 14) that can be manufactured through fewer times of the total of five photolithographic processes, and a manufacturing method therefor.

(Configuration)

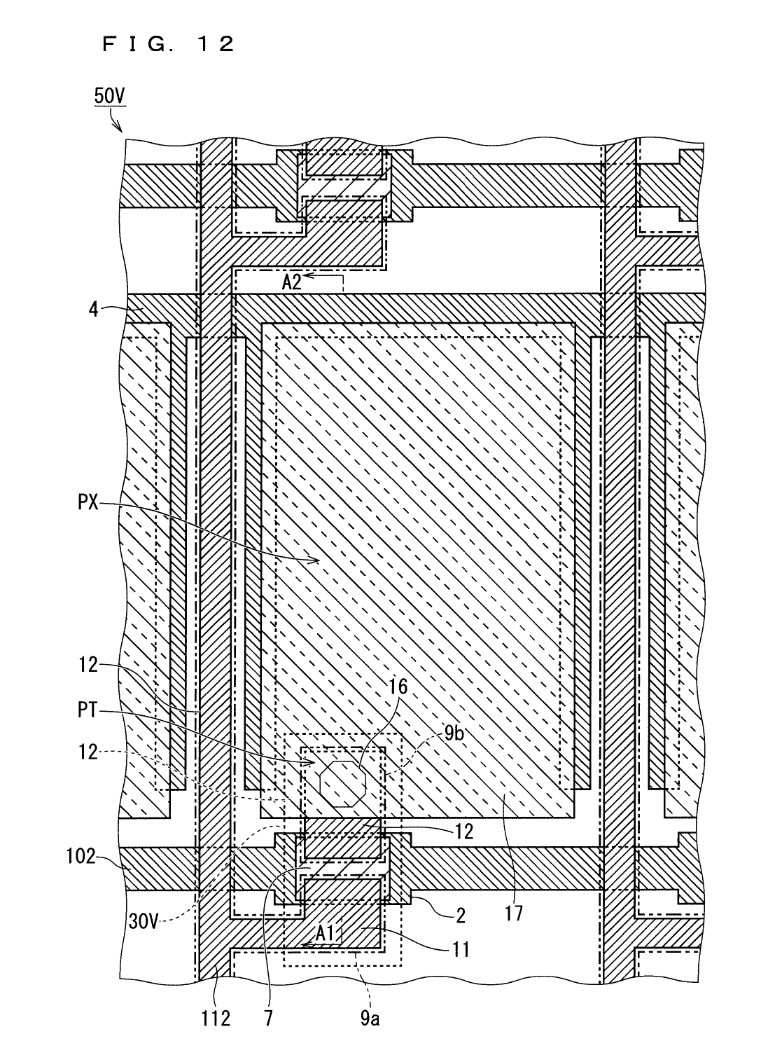

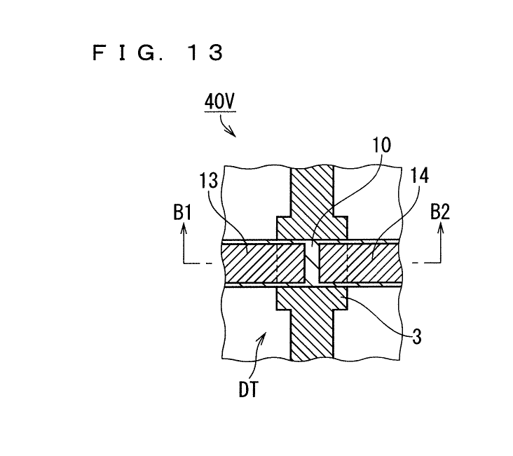

FIG. 12 is a partial plan view schematically illustrating a configuration of a unit structure provided in a display region 50V of the TFT substrate 100V. The pixel TFT 30 is provided in each unit structure. FIG. 13 is a partial cross-sectional view schematically illustrating a configuration of a drive TFT 40V provided in the drive transistor region DT included in a frame region 60V (FIG. 14) of the TFT substrate 100V. In this modified example, a configuration of the drive TFT 40V is used as a configuration of the drive TFTs 40 to 42 (FIG. 3). FIG. 14 is a partial cross-sectional view taken along the line A1-A2 (FIG. 12) and the line B1-B2 (FIG. 13). Note that, in the plan views of FIG. 12 and FIG. 13, for the sake of simplifying the drawings, a configuration formed of an insulator is not shown, and hatching is employed.

Also in this preferred embodiment similarly to the first preferred embodiment, the second conductive film M2 is arranged on the oxide semiconductor film S2 having the source contact layer 9a, the drain contact layer 9b, and the second semiconductor layer 10 as a plurality of patterns; the second conductive film M2 has the first source electrode 11, the first drain electrode 12, the second source electrode 13, and the second drain electrode 14 as a plurality of patterns. Note that, in this preferred embodiment, the edge of the second conductive film M2 is arranged on the oxide semiconductor film S2 separately away from the edge of the oxide semiconductor film S2. Specifically, the first source electrode 11 has its edge arranged on the source contact layer 9a separately away from the edge of the source contact layer 9a. Further, the first drain electrode 12 has its edge arranged on the drain contact layer 9b separately away from the edge of the drain contact layer 9b. Further, the second source electrode 13 and the second drain electrode 14 have their edges arranged on the second semiconductor layer 10 separately away from the edge of the second semiconductor layer 10.

For this reason, in this preferred embodiment, the second semiconductor layer 10 of the oxide semiconductor film S2 does not have an isolated island-like pattern as illustrated in the first preferred embodiment (FIG. 5) but has a pattern crossing over the second gate electrode 3 along an extending direction of the second source electrode 13 and the second drain electrode 14 in a plan view (FIG. 13). Accordingly, as illustrated in the cross-sectional configuration of FIG. 14, the second source electrode 13 and the second drain electrode 14 are arranged on a stepped portion generated due to the second gate electrode 3 with intermediation of not only the gate insulation film 5 but also the oxide semiconductor film S2. With the cross-sectional structure as described above, generation of unintentional disconnection (step disconnection failure) in the second source electrode 13 and the second drain electrode 14, which is caused by coverage failure in the above-mentioned stepped portion, can be prevented or suppressed.

Further, as indicated by the two-dot chain line in the plan view of FIG. 12, the source contact layer 9a is provided below the first source electrode 11 and the source wire 112 in such a manner as to have a shape substantially the same as the shapes of the first source electrode 11 and the source wire 112 and as to have the edge thereof slightly projecting outward. With this, generation of step disconnection failure of the source wire 112 at an intersecting portion of the source wire 112 and the gate wire 102 can be prevented or suppressed.

(Manufacturing Method)

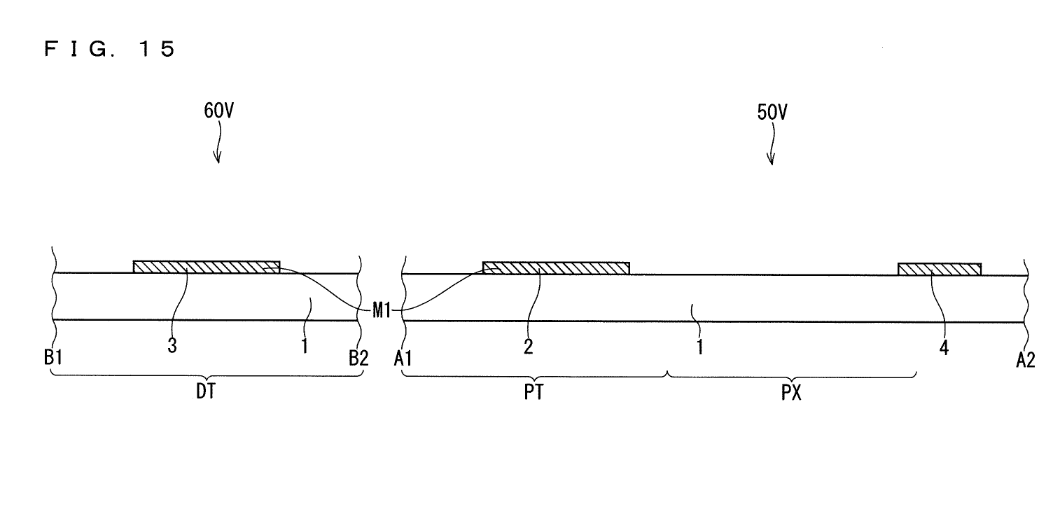

FIG. 15 to FIG. 23 are partial cross-sectional views schematically illustrating a manufacturing method for the TFT substrate 100V (FIG. 14) in a field of view corresponding to FIG. 14 in order of processes.

Referring to FIG. 15, a process similar to the process of FIG. 7 of the first preferred embodiment is performed. That is, the first conductive film M1 is formed on an entire main surface of the substrate 1 on one side (upper surface in the drawing). Then, a pattern is provided to the first conductive film M1 using the first photolithographic process such that the first gate electrode 2, the second gate electrode 3, and the common electrode 4 are formed.

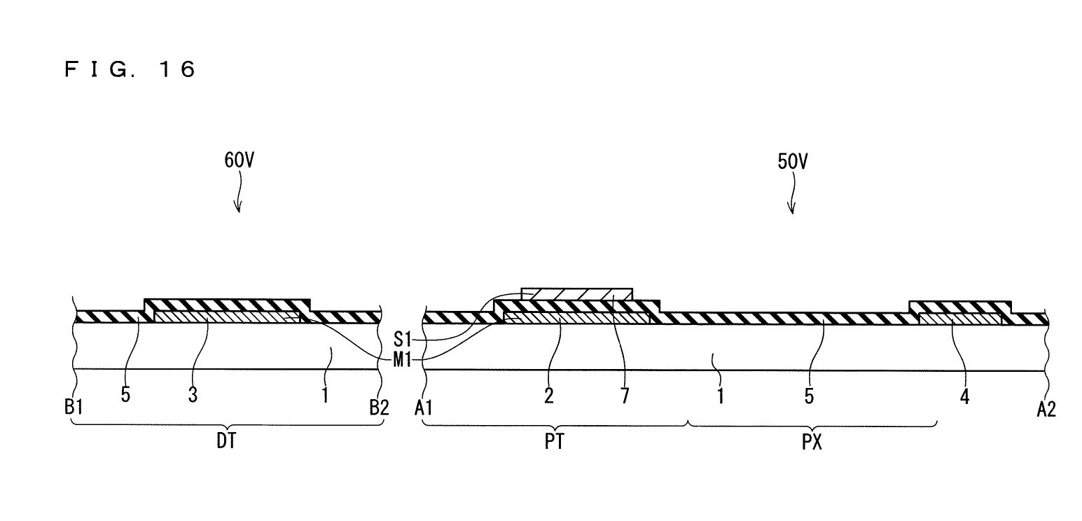

Referring to FIG. 16, a process similar to the process of FIG. 8 of the first preferred embodiment is performed. That is, the gate insulation film 5 is formed on the first gate electrode 2, the second gate electrode 3, and the common electrode 4. Then, the amorphous silicon film Si is formed on the gate insulation film 5. Next, a pattern is provided to the amorphous silicon film S1 using the second photolithographic process such that the first semiconductor layer 7 opposed to the first gate electrode 2 with intermediation of the gate insulation film 5 is formed.

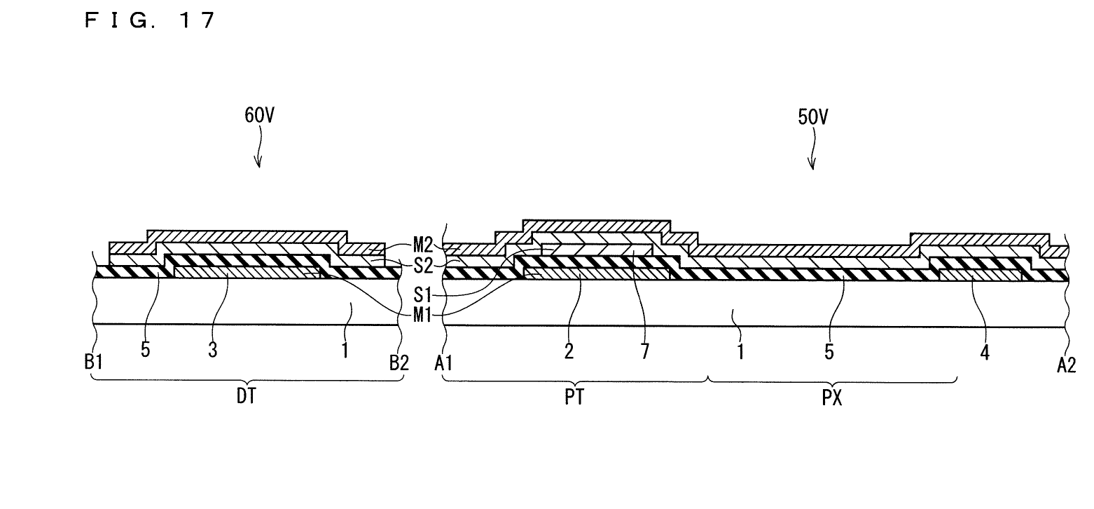

Referring to FIG. 17, similarly to the first preferred embodiment, the oxide semiconductor film S2 is formed on the gate insulation film 5 on which the first semiconductor layer 7 has been provided. After that, in this preferred embodiment, the second conductive film M2 is formed on the oxide semiconductor film S2 without patterning the oxide semiconductor film S2. A deposition method of the second conductive film M2 may be the same as that of the first preferred embodiment.

Next, a process for providing a pattern to the oxide semiconductor film S2 and a process for providing a pattern to the second conductive film M2 are performed. Those processes are described below.

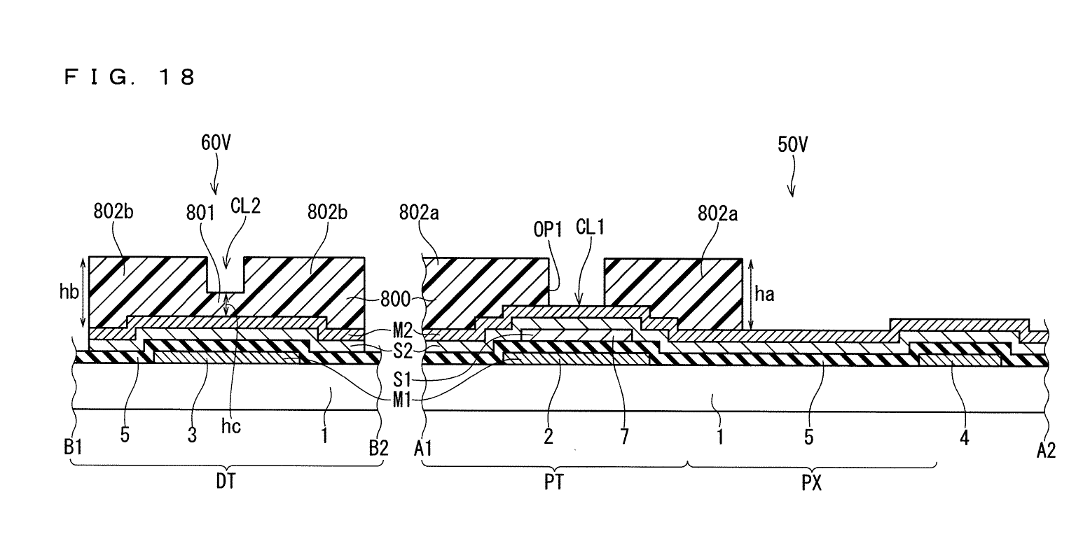

Referring to FIG. 18, a photoresist layer 800 is formed on the second conductive film M2 with a coating method. The photoresist layer 800 is formed of, for example, a photoresist material that is formed of a novolak-type positive photosensitive resin.

Next, the photoresist layer 800 is patterned using the third photolithographic process. As a result, the photoresist layer 800 has a first opening OP1, a first region 801, and second regions 802a, 802b having a thickness larger than that of the first region 801. The first opening OP1 and the second region 802a are to be used as an etching mask for forming the channel region CL1. Specifically, in a plan view, the channel region CL1 is to be formed in a region corresponding to the first opening OP1. The first region 801 and the second region 802b are to be used as an etching mask for forming the channel region CL2. Specifically, in a plan view, the channel region CL2 is to be formed in a region corresponding to the first region 801.

In the illustrated example, the first region 801, the second region 802a, and the second region 802b have a thickness hc, a thickness ha, and a thickness hb, respectively. The thickness ha and the thickness hb are each larger than the thickness hc. The thickness ha and the thickness hb may be equal to each other. For example, the condition of the thickness hc=1.0 μm, the thickness ha=2.5 μm, and the thickness hb=2.5 μm is used. Note that, slight difference in thickness may exist in each of the first region 801, and the second region 802a and the second region 802b. Such difference may be generated due to the shape of a surface on which the photoresist layer 800 is formed, and is approximately of a size of the thickness of the first conductive film M1 and the amorphous silicon film 51, for example.

As described above, the photoresist layer 800 having the first opening OP1, the first region 801, and the second regions 802a and 802b can be formed by firstly applying and forming a positive photoresist on the substrate 1 so as to have a desired maximum film thickness (2.5 μm in the above example) and then controlling a light exposure value at the time of exposing the photoresist in the photolithographic process at multiple stages. For example, at the time of exposing the photoresist, of the photoresist layer 800, a region to be the first opening OP1 is directly irradiated with exposure light, a region to be the first region 801 is irradiated with reduced exposure light, and regions to be the second regions 802a, 802b are shielded from exposure light. After that, when a developing process for the resist is executed, the photoresist is completely removed in the region directly irradiated with exposure light, is reserved having a maximum film thickness in the region shielded from light, and is reduced in film thickness in the region irradiated with reduced light. Note that, as a method of controlling a light exposure value at multiple stages as described above, a publicly known photolithographic process using a gray tone or halftone photomask may be used.

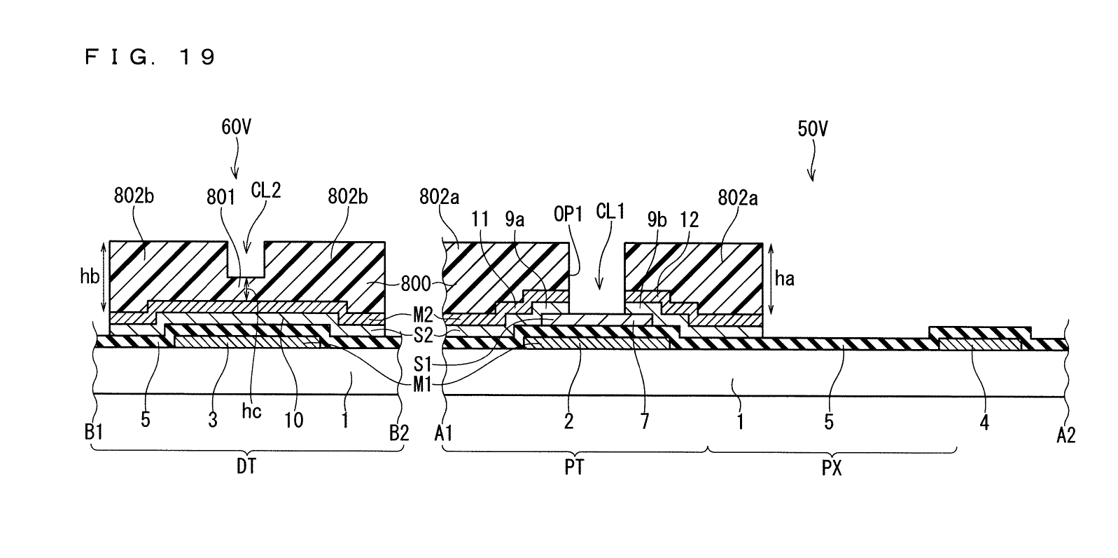

Referring to FIG. 19, in the first opening OP1 of the photoresist layer 800, the second conductive film M2 is etched. With this, the first source electrode 11 and the first drain electrode 12 are formed. Subsequently, the oxide semiconductor film S2 is etched in the first opening OP1, thereby forming the source contact layer 9a and the drain contact layer 9b. With this, the channel region CL1 is provided in the first semiconductor layer 7. Note that, an etching method for each of the second conductive film M2 and the oxide semiconductor film S2 may be the same as that of the first preferred embodiment.

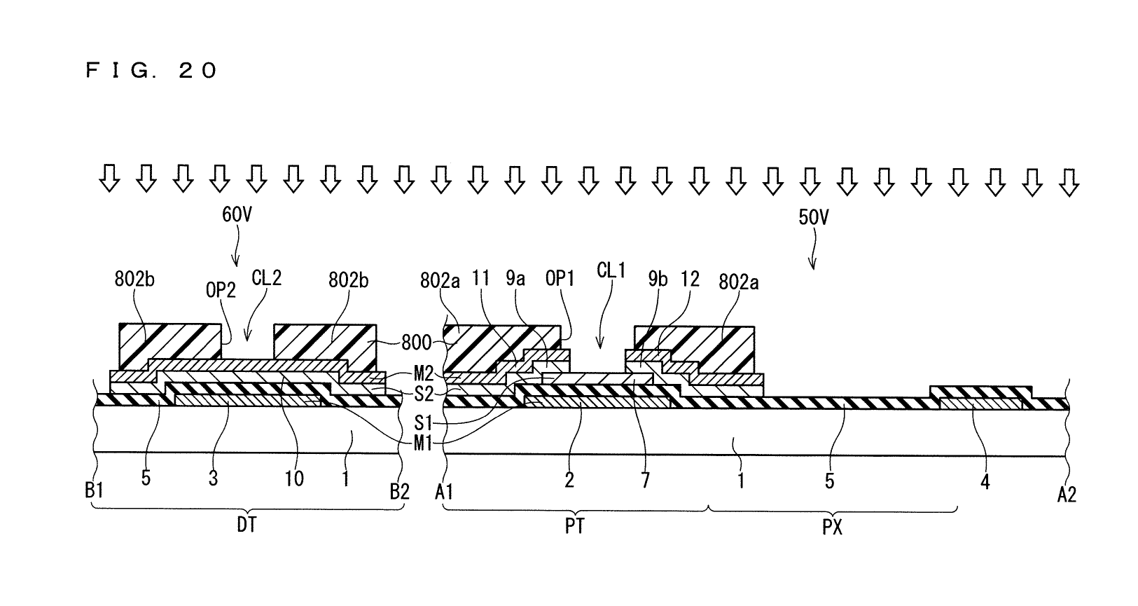

Referring further to FIG. 20, next, through partial removal of the photoresist layer 800, the first region 801 is changed into a second opening OP2 while the second region 802a and the second region 802b are at least partially reserved. Specifically, through irradiation of the entire substrate 1 with oxygen (O₂) plasma (refer to the arrows of FIG. 20), ashing is performed on the entire photoresist layer 800. With the ashing, the thickness of the photoresist layer 800 is entirely reduced. With this, the first region 801 having a relatively small thickness is completely removed, and the second regions 802a and 802b having a relatively large thickness are reserved with the thickness thereof being reduced. Further, not only the thickness is reduced as described above, but the pattern shape of the photoresist layer 800 in a plan view is also reduced. That is, in a plan view, the edge of the photoresist layer 800 is recessed inward. With this, an end portion of the second conductive film M2 is exposed on the oxide semiconductor film S2.

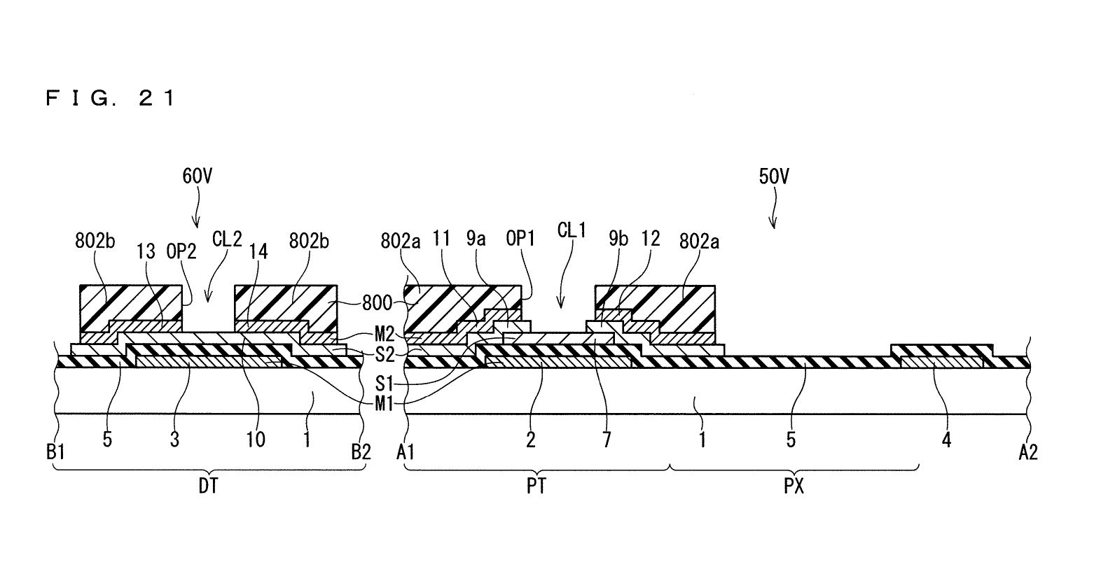

Referring to FIG. 21, in the second opening OP2 of the photoresist layer 800, the second conductive film M2 is etched. With this, the second source electrode 13 and the second drain electrode 14 are formed. That is, the channel region CL2 is provided in the second semiconductor layer 10. Note that, an etching method for the second conductive film M2 may be the same as that of the first preferred embodiment.

Pattern shapes of the second regions 802a and 802b are, as described above, reduced as compared to shapes before ashing. Therefore, in a plan view, the second conductive film M2 patterned by using the photoresist layer 800 after ashing as an etching mask has the edge recessed inward with respect to the edge of the oxide semiconductor film S2 patterned by using the photoresist layer 800 before ashing as an etching mask.

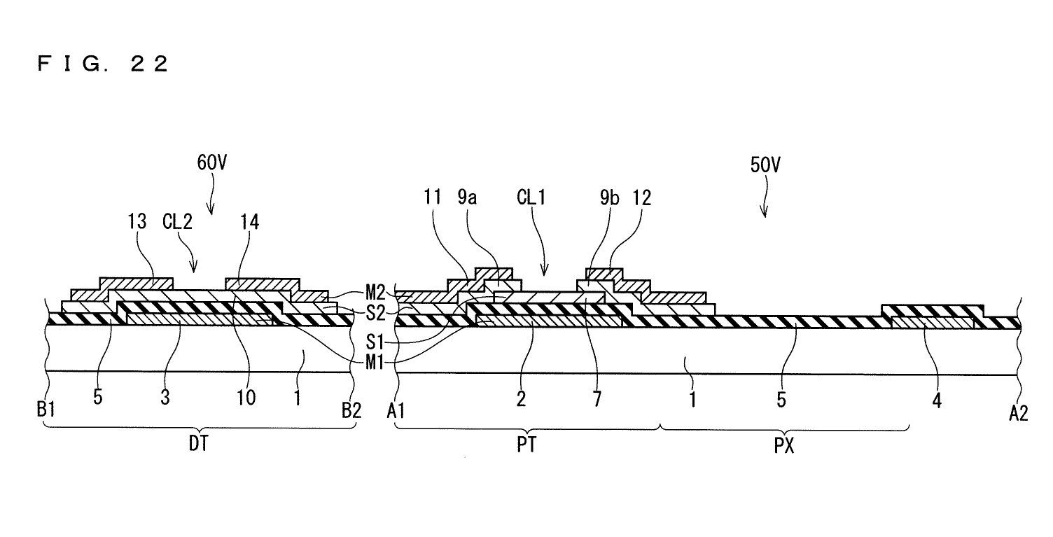

Referring further to FIG. 22, the photoresist layer 800 is removed. In this modified example as being illustrated, an end portion of the oxide semiconductor film S2 and an end portion of the second conductive film M2 have an ordered stepped shape as illustrated in FIG. 21.

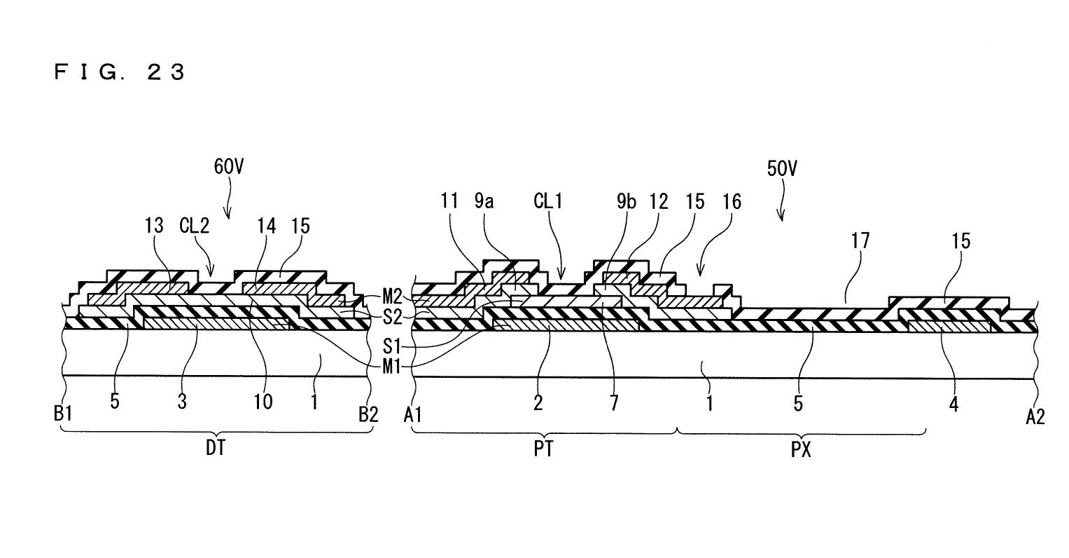

Referring to FIG. 23, using the fourth photolithographic process, a process similar to the process of FIG. 11 of the first preferred embodiment is performed. That is, the protective insulation film 15 having the contact hole 16 is formed. In this preferred embodiment, at the point of time when a film to be the protective insulation film 15 is formed, as described above, the end portion of the oxide semiconductor film S2 and the end portion of the second conductive film M2 have an ordered stepped shape. Therefore, deposition can be performed with satisfactory coverage even in the stepped portion.

Referring to FIG. 14 again, using the fifth photolithographic process, similarly to the first preferred embodiment, the pixel electrode 17 connected to the first drain electrode 12 is formed. From the above, the TFT substrate 100V can be obtained. The total of six photolithographic processes are performed in the first preferred embodiment. In this modified example, however, the number of times of the photolithographic processes can be decreased to the total of five times.

### Second Preferred Embodiment

In the first preferred embodiment, detailed description has been given of the case where the gate insulation film 5 is a SiN single layer film obtained with the CVD method. A SiN film obtained with the CVD method is also generally used as a gate insulation film of a related-art BCE-type TFT having an amorphous silicon film as a channel layer, and is known to be capable of attaining satisfactory TFT characteristics. On the other hand, in a case of a TFT using an oxide semiconductor film as a channel layer, satisfactory TFT characteristics may not be sufficiently attained when a SiN film is used as a gate insulation film thereof. The reason therefor is presumed to be as follows.

Generally, in the deposition of a SiN film with the CVD method, silane (SiH₄), ammonia (NH₃), and the like are used as a material gas. For this reason, a large amount of hydrogen (H) atoms are contained in a SiN film. Therefore, at the time of forming an oxide semiconductor film on the SiN film, the H atoms diffuse into the oxide semiconductor film from the SiN film. As a result, the oxide semiconductor film is unintentionally reduced. Therefore, desired semiconductor characteristics may not be attained.

In view of the above, in a case where the oxide semiconductor film S2 is used as a channel layer, it is preferable that, at least, a portion of the gate insulation film 5 that comes in direct contact with the oxide semiconductor film S2 be not a SiN film but another insulation film having low H concentration. As such an insulation film, for example, an aluminium oxide (Al₂O₃) film, a hafnium oxide (HfO₂) film, a yttrium oxide (Y₂O₃) film, a silicon oxide (SiO₂) film, or the like formed with a sputtering method may be used. Further, even in a case where the CVD method is used, a silicon oxide (SiO, SiO₂) film having low H concentration can be formed by using silane (SiH₄) and dinitrogen monoxide (N₂O) as a material gas. For example, according to a document: W. A. Lanford et al., “The hydrogen content of plasma-deposited silicon nitride,” Journal of Applied Physics, 1978, vol. 49, pp. 2473-2477, there is a reported case in which, when deposition is performed with a plasma CVD method, H concentration in a SiN film is from 20 to 25 at % and H concentration in a SiO film is from 5 to 6 at %.

In addition to having low H concentration as described above, a silicon oxide film (SiO film) has a characteristic of containing oxygen (O) atoms. For this reason, in a case where an oxide semiconductor film is formed on a silicon oxide film, 0 atoms are less liable to diffuse into the silicon oxide film from the oxide semiconductor film. Therefore, unintentional reduction of the oxide semiconductor film is suppressed. On the other hand, a SiO film is known to have low barrier property (blocking property) against impurity elements that affect TFT characteristics, such as water moisture (H₂O), hydrogen (H₂), sodium (Na), and potassium (K).

In view of the above, in this second preferred embodiment, the gate insulation film 5 is not a single layer film, but is formed of a SiN film (more generally, a nitride film) and a SiO film (more generally, an oxide film) that are stacked mutually. The first semiconductor layer 7 formed of a-Si is arranged directly on the SiN film, and the second semiconductor layer 10 formed of an oxide semiconductor is arranged directly on the SiO film.

(Configuration)

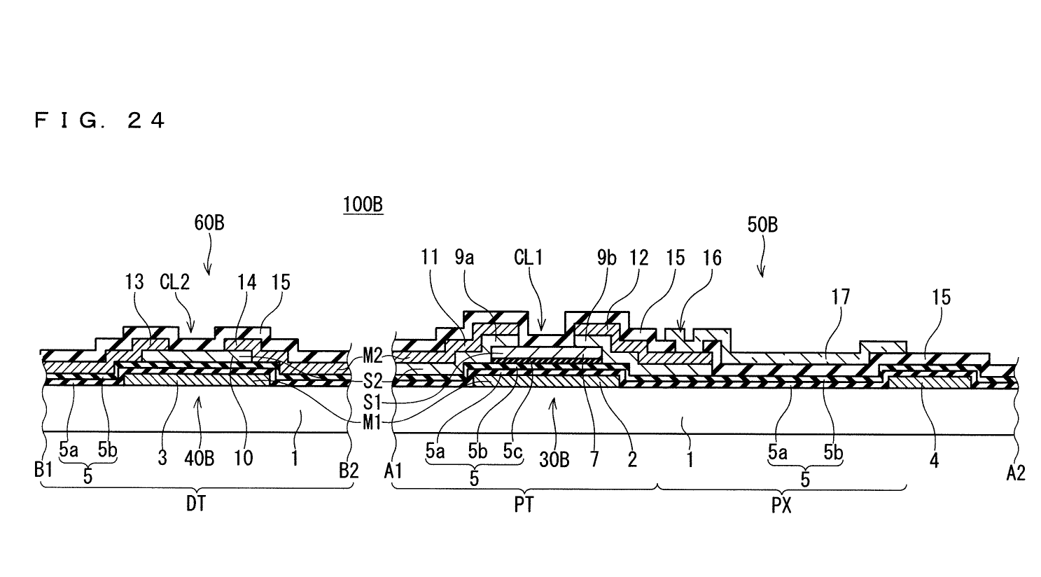

FIG. 24 is a partial cross-sectional view schematically illustrating a configuration of a TFT substrate 100B (thin film transistor substrate) according to the second preferred embodiment of the present invention in a field of view similar to FIG. 6 (first preferred embodiment). In the first preferred embodiment (FIG. 6) described above, the pixel TFT 30 is provided in the display region 50 and the drive TFT 40 is provided in the frame region 60; in this preferred embodiment, a pixel TFT 30B (pixel transistor) is provided in a display region 50B and a drive TFT 40B (drive transistor) is provided in a frame region 60B instead.

In this preferred embodiment, as the gate insulation film 5, stacked films having a SiN film 5a (first nitride film), a SiO film 5b (oxide film), and a SiN film 5c (second nitride film) that are stacked on the substrate 1 in the mentioned order are used. The first semiconductor layer 7 is in contact with the SiN film 5c, and the second semiconductor layer 10 is in contact with the SiO film 5b. Further, the SiN film 5a is arranged between the substrate 1 and each of the first semiconductor layer 7 and the second semiconductor layer 10. For example, the thickness of the SiN film 5a is 400 nm, the thickness of the SiO film 5b is 50 nm, and the thickness of the SiN film 5c is 50 nm.

In a region where the first semiconductor layer 7 formed of the amorphous silicon film Si is formed, the gate insulation film 5 includes the three layers of the SiN film 5a, the SiO film 5b, and the SiN film 5c. Therefore, the first semiconductor layer 7 formed of the amorphous silicon film Si is arranged so as to come in contact with the top of the SiN film 5c. Further, in the outside of the region where the first semiconductor layer 7 is arranged, the gate insulation film 5 includes two layers of the SiN film 5a and the SiO film 5b, and does not include the SiN film 5c. Therefore, the second semiconductor layer 10 formed of the oxide semiconductor film S2 is arranged so as to come in contact with the top of the SiO film 5b.

Configuration other than the above is substantially the same as the TFT substrate 100 (FIG. 6) of the first preferred embodiment, and therefore description thereof is omitted.

(Manufacturing Method)

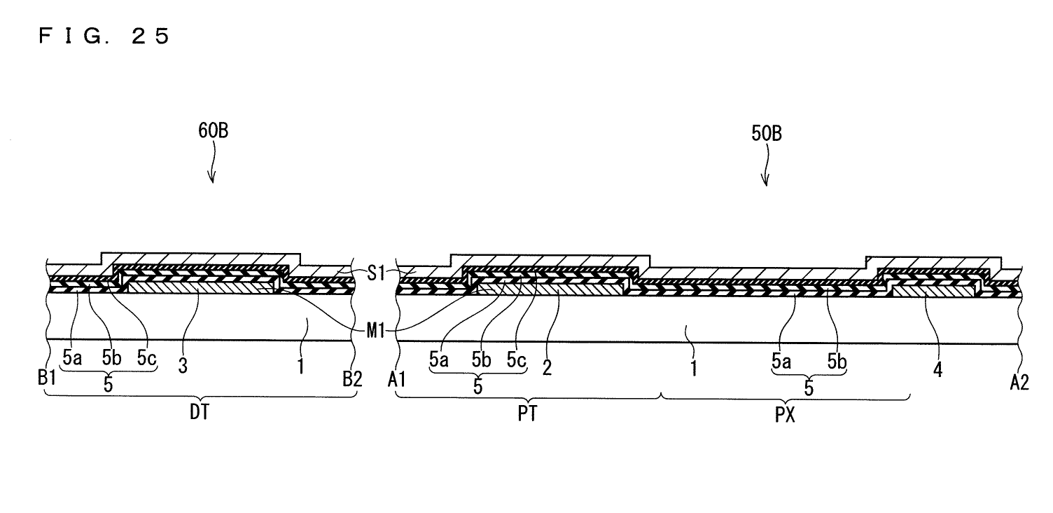

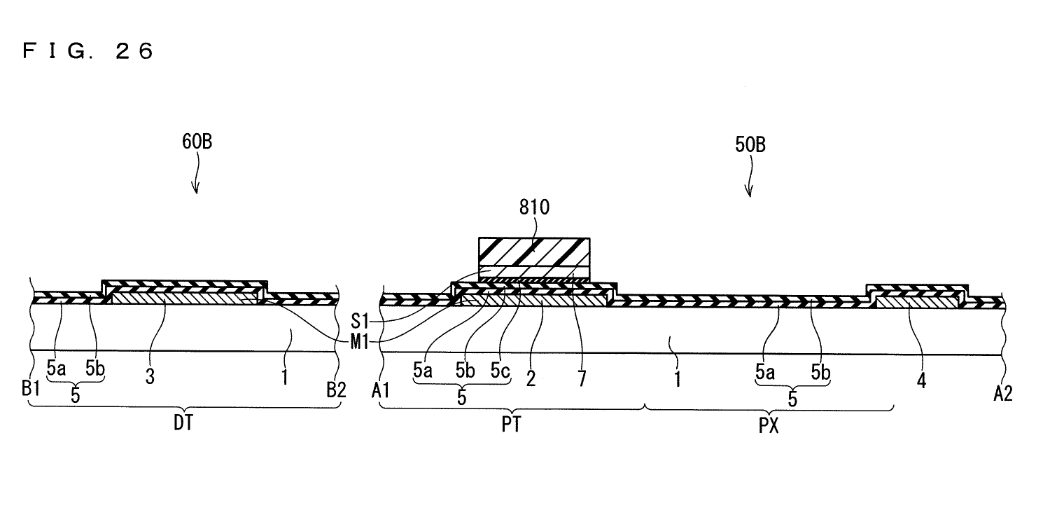

FIG. 25 and FIG. 26 are each a partial cross-sectional view illustrating a process of a manufacturing method for the TFT substrate 100B (FIG. 24) in a field of view corresponding to FIG. 24.

Referring to FIG. 25, after the first conductive film M1 is formed on the substrate 1 similarly to the process of FIG. 7 of the first preferred embodiment, the SiN film 5a is formed on the substrate 1. Next, the SiO film 5b is formed on the SiN film 5a. Next, the SiN film 5c is formed on the SiO film 5b. With this, the gate insulation film 5 having a stacking structure is formed. As a deposition method, for example, the CVD method is used. As a material gas for the SiN film, silane (SiH₄) and ammonia (NH₃) may be used. As a material gas for the SiO film, silane (SiH₄) and dinitrogen monoxide (N₂O) may be used.

Next, the amorphous silicon film Si is formed on the gate insulation film 5. A deposition method may be the same as the process of FIG. 8 of the first preferred embodiment.

Referring to FIG. 26, on a portion of the amorphous silicon film Si where the first semiconductor layer 7 (FIG. 24) is to be formed, a photoresist layer 810 is formed using a photolithographic process. Next, the amorphous silicon film S1 is etched using the photoresist layer 810 as a mask, thereby forming the first semiconductor layer 7. An etching method may be the same as that of the first preferred embodiment.

Further, the SiN film 5c is etched using the photoresist layer 810 as a mask. With this, the SiN film 5c is patterned such that a portion of the SiN film 5c positioned between the first semiconductor layer 7 and the SiO film 5b is reserved and that the other portion is removed. This etching is performed, for example, by dry etching using an etching gas containing a sulfur hexafluoride (SF₆) gas containing fluorine atoms, and an oxygen (O₂) gas. After that, the photoresist layer 810 is removed.

After that, a process for forming the oxide semiconductor film S2 and the like are performed in a manner substantially the same as the process of FIG. 9 and the subsequent processes of the first preferred embodiment. With this, the TFT substrate 100B (FIG. 24) is manufactured.

Note that, in the above-mentioned manufacturing method, the SiO film 5b is formed with the CVD method as an oxide film. However, an oxide film of other types may be formed instead. For example, a metallic oxide film having insulation property, such as a SiO film, an aluminium oxide (AlO) film, a hafnium oxide (HfO) film, and a yttrium oxide (YO) film, may be formed with a sputtering method. Further, at least any one of the SiN film 5a and the SiN film 5c may be replaced with a nitride film of other types, or may be replaced with an insulation film having high barrier property other than a nitride film.

Further, after the process illustrated in FIG. 26, a process substantially the same as the process of FIG. 17 and the subsequent processes of the modified example of the first preferred embodiment may be performed. With this, effects similar to those in a case of the modified example of the first preferred embodiment can be obtained also in this preferred embodiment.

### Summary of Effects

According to the TFT substrate 100B of this preferred embodiment, the first semiconductor layer 7 is arranged directly on the SiN film 5c. The SiN film has high barrier property, and hence characteristics of the pixel TFT 30 using the first semiconductor layer 7 can be enhanced. Further, the second semiconductor layer 10 formed of an oxide semiconductor is arranged directly on the SiO film 5b. With this, as compared to the case where the second semiconductor layer 10 is arranged directly on a non-oxide layer, particularly on a layer having high H concentration in a film thereof, unintentional reduction of the oxide semiconductor forming the second semiconductor layer 10 can be suppressed. Therefore, characteristics of the drive TFT 40 using the second semiconductor layer 10 can be enhanced. From the above, reliability of the TFT substrate 100B can be enhanced, and further, display quality of the LCD 500 (FIG. 1) using the TFT substrate 100B can be enhanced.

Further, the SiN film 5a is arranged between the SiO film 5b and the substrate 1. With this, the SiN film having high barrier property is arranged not only between the substrate 1 and the first semiconductor layer 7 but also between the substrate 1 and the second semiconductor layer 10. Therefore, characteristics of the drive TFT 40 using the second semiconductor layer 10 can be further enhanced.

Further, according to the manufacturing method of this preferred embodiment, patterning of the SiN film 5c is performed using an etching mask for patterning of the first semiconductor layer 7. Therefore, the patterned SiN film 5c can be provided without requiring additional photolithographic processes.

In addition, effects substantially the same as those of the first preferred embodiment can be obtained.

### Third Preferred Embodiment

In the above first and second preferred embodiments and modified examples thereof, description has been given of a case of where a vertical electric field driving mode as typified by a light transmitting TN mode or VA mode is used. Through modification of such configurations, substantially the same effects can be obtained also in a horizontal electric field driving mode as typified by an FFS mode. In this preferred embodiment, description is given of a case where the FFS mode is used.

(Configuration)

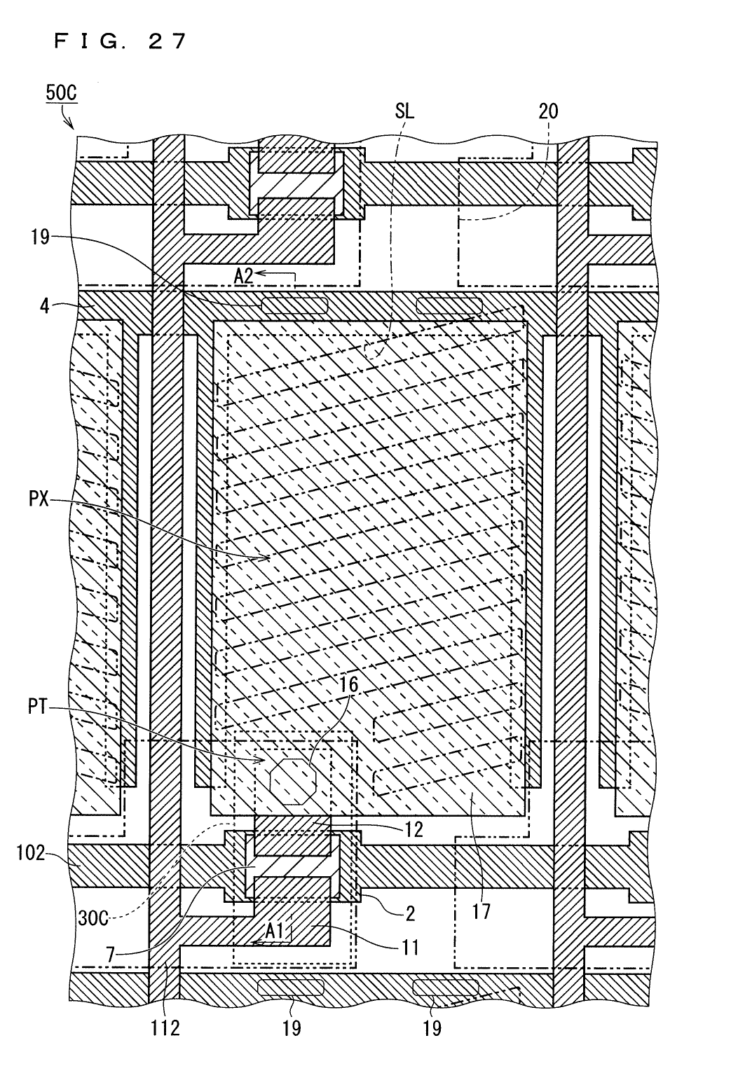

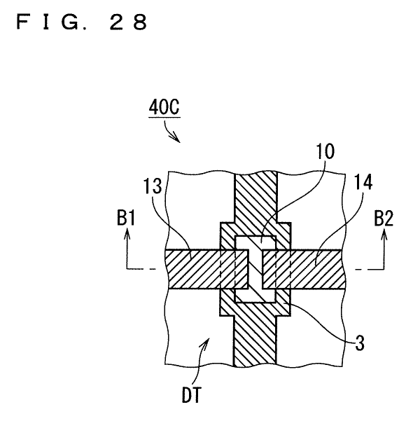

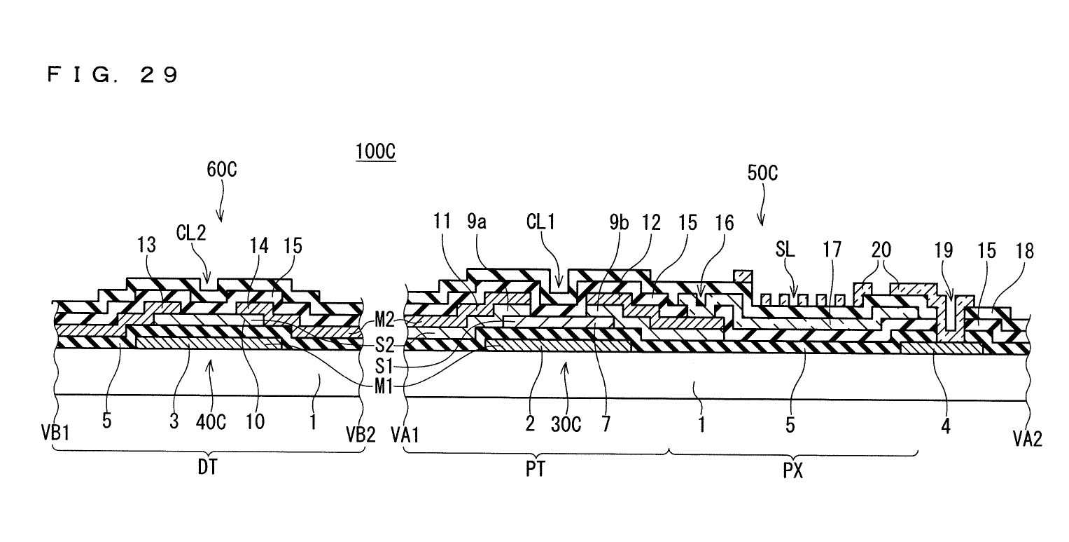

FIG. 27 is a partial plan view schematically illustrating a configuration of a unit structure provided in a display region 50C of a TFT substrate 100C (FIG. 29) according to a third preferred embodiment of the present invention in a field of view corresponding to FIG. 4 (first preferred embodiment). A pixel TFT 30C is provided in each unit structure. FIG. 28 is a partial plan view schematically illustrating a configuration of a drive TFT 40C provided in the drive transistor region DT included in a frame region 60C of the TFT substrate 100C in a field of view corresponding to FIG. 5. In this preferred embodiment, the configuration of the drive TFT 40C is used as a configuration of the drive TFTs 40 to 42 (FIG. 3). FIG. 29 is a partial cross-sectional view taken along the line A1-A2 of FIG. 27 and the line B1-B2 of FIG. 28. Note that, in the plan views of FIG. 27 and FIG. 28, for the sake of simplifying the drawings, a configuration formed of an insulator is not shown, and hatching is employed.

The TFT substrate 100C (FIG. 29) has a stacking structure similar to a stacking structure from the substrate 1 to the pixel electrode 17 of the TFT substrate 100 (FIG. 6) according to the first preferred embodiment. Therefore, detailed description of this part is omitted. The TFT substrate 100C has, further on the stacking structure, an interlayer insulation film 18 and a counter electrode 20.

The interlayer insulation film 18 is provided on the pixel electrode 17. A contact hole 19 is provided in the interlayer insulation film 18. The contact hole 19 is arranged, in a plan view, in a region overlapping the common electrode 4 and not overlapping the pixel electrode 17. The contact hole 19 passes through the protective insulation film 15 and the gate insulation film 5 as well as the interlayer insulation film 18, and reaches the common electrode 4.

The counter electrode 20 is formed of a transparent conductive film. The counter electrode 20 is provided on the interlayer insulation film 18 as illustrated in FIG. 29. The counter electrode 20 has a portion overlapping the pixel region PX as indicated by the two-dot chain line in FIG. 27, and has a portion opposed to the pixel electrode 17 in the thickness direction as illustrated in FIG. 29. In the example illustrated in FIG. 27, the counter electrode 20 is provided in such a continuous shape as to horizontally and vertically cross adjacent pixel regions PX. The counter electrode 20 is connected to the common electrode 4 through the contact hole 19. With this, a certain common potential signal is applied from the common electrode 4 to the counter electrode 20.

A slit opening SL is provided in the counter electrode 20. With this structure, when a signal voltage is applied between the pixel electrode 17 and the counter electrode 20, an electric field substantially horizontal with respect to the surface of the substrate is generated above the counter electrode 20. With this, the TFT substrate 100C is applicable to an LCD of an FFS mode, which is a horizontal electric field driving mode. In order to obtain an LCD of an FFS mode, it suffices that a configuration substantially the same as the LCD 500 (FIG. 1) of the first preferred embodiment be used with use of the TFT substrate 100C. Note that, a comb-like opening may be provided instead of the slit opening SL.

(Manufacturing Method)

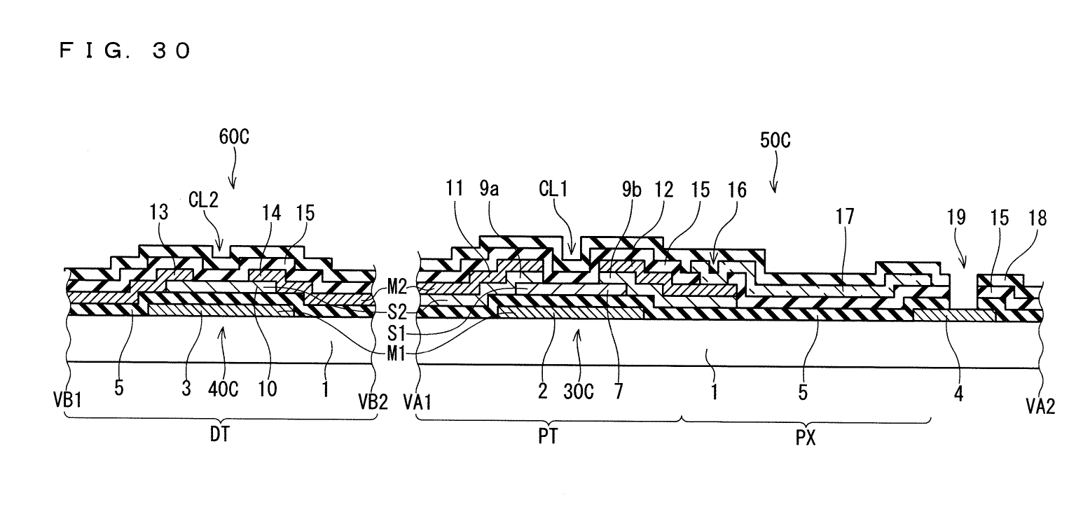

Process until the formation of the pixel electrode 17 is substantially the same as that of the first preferred embodiment, and therefore description thereof is omitted. FIG. 30 is a partial cross-sectional view schematically illustrating a process of a manufacturing method for the TFT substrate 100C in a field of view corresponding to FIG. 29.

On the entire surface of the substrate 1 on which the patterned pixel electrode 17 has been provided using the sixth photolithographic process, the interlayer insulation film 18 is formed. For example, a SiN film having a thickness of 100 nm is formed with the CVD method.

After that, a photoresist pattern is formed using the seventh photolithographic process. With etching using the photoresist pattern as a mask, the contact hole 19 is formed. For example, etching of the interlayer insulation film 18 formed of a SiN film, the protective insulation film 15 formed of a SiO film and a SiN film, and the gate insulation film 5 formed of a SiN film is performed by dry etching using an etching gas obtained by adding oxygen (O₂) to sulfur hexafluoride (SF₆). After that, the photoresist pattern is removed, thereby forming the contact hole 19 that exposes a part of the common electrode 4 as illustrated in FIG. 30.

Referring to FIG. 29 again, on the interlayer insulation film 18 on which the contact hole 19 has been provided, a conductive film to be a material for the counter electrode 20 is formed. This deposition method may be conducted by a method similar to the deposition for the pixel electrode 17.

After that, a photoresist pattern is formed using the eighth photolithographic process. The above-mentioned conductive film is etched using the photoresist pattern as a mask, thereby forming the counter electrode 20. For example, an amorphous ITO film is patterned by wet etching using a solution containing an oxalic acid. After that, the photoresist pattern is removed, thereby obtaining the TFT substrate 100C.

Note that, the method of manufacturing an LCD using the TFT substrate 100C is substantially the same as the method of manufacturing the LCD 500 (FIG. 1) using the TFT substrate 100, which has been described in the first preferred embodiment.

### Summary of Effects

According to this preferred embodiment, effects substantially the same as those of the first preferred embodiment can be obtained in a horizontal electric field driving mode. Further, the use of the FFS mode of the horizontal electric field drive realizes a wide viewing angle, and therefore display performance can further be enhanced.

Note that, in this third preferred embodiment, description has been given of the configuration and the manufacturing method for the TFT substrate 100C obtained on the basis of the TFT substrate 100 (first preferred embodiment), but the first and second preferred embodiments and the modified examples thereof may be employed as the basis thereof.

Further, in the above-mentioned first to third preferred embodiments, detailed description has been given of each structure of a pixel TFT having the first semiconductor layer 7 formed of the amorphous silicon film Si as a channel layer and a drive TFT having the second semiconductor layer 10 formed of the oxide semiconductor film S2 as a channel layer, but another structure may be adopted. When the pixel TFT being arranged in a display region and connected to a pixel electrode has a semiconductor layer formed of a-Si as a channel layer and the drive TFT being arranged in a frame region and forming a drive circuit has a semiconductor layer formed of an oxide semiconductor film as a channel layer, a narrow-framed LCD having high display quality and high reliability can be obtained at a low cost.

Further, addition of a light shielding layer in a pixel region leads to reduction of a pixel aperture ratio (ratio of an effective display region in the display region) and adversely affects luminance, power consumption, or the like of a display image, and is therefore subjected to a limitation. In contrast, a frame region is often a region free from such a limitation and is supposed to be shielded from light in the first place. Accordingly, the above-mentioned TFT substrate and the above-mentioned LCD using the TFT substrate are optimized in view of the fact that the use of an oxide semiconductor as a channel layer enhances performance of the TFT but reduces resistance to light deterioration, the fact that the use of a-Si as a channel layer deteriorates performance of the TFT but enhances resistance to light deterioration, and the fact that light can be blocked without adversely affecting performance of the LCD in a drive TFT unlike a pixel TFT.

In the present invention, concerning the configurations, the materials, and the like, each of the preferred embodiments and modified examples thereof may be freely combined, and each of the preferred embodiments may be modified or omitted as appropriate within the scope of the invention. For example, the thin film transistor substrate, the manufacturing method for a thin film transistor substrate, and the thin film transistor of the present invention are not limited to application to a liquid crystal display, and are also applicable to another display device and an electro-optical device including a pixel electrode and a thin film transistor connected to the pixel electrode.

While the invention has been shown and described in detail, the foregoing description is in all aspects illustrative and not restrictive. It is therefore understood that numerous modifications and variations can be devised without departing from the scope of the invention.

What is claimed is:

1. A thin film transistor substrate comprising:
a substrate;
a first gate electrode provided on the substrate;
a gate insulation film provided on the first gate electrode;
a first semiconductor layer that is provided on the gate insulation film, is opposed to the first gate electrode with intermediation of the gate insulation film, and is formed of amorphous silicon;
a first contact layer having a portion arranged on the first semiconductor layer and being formed of an oxide semiconductor;
a second contact layer having a portion arranged on the first semiconductor layer separately away from the first contact layer and being formed of an oxide semiconductor;
a first electrode connected to the first contact layer; and
a second electrode connected to the second contact layer.

2. The thin film transistor substrate according to claim 1, further comprising:
a second gate electrode being provided on the substrate, the gate insulation film being provided on the second gate electrode;
a second semiconductor layer that is provided on the gate insulation film, is opposed to the second gate electrode with intermediation of the gate insulation film, and is formed of an oxide semiconductor;
a pixel electrode connected to the second electrode;
a third electrode having a portion arranged on the second semiconductor layer; and
a fourth electrode having a portion arranged on the second semiconductor layer separately away from the third electrode.

3. The thin film transistor substrate according to claim 2, wherein the first contact layer, the second contact layer, and the second semiconductor layer contain at least one type of metallic element in common.

4. The thin film transistor substrate according to claim 2, wherein the thin film transistor substrate comprises a first transistor having the first semiconductor layer and a drive circuit for driving the first transistor, and the drive circuit comprises a second transistor having the second semiconductor layer.

5. The thin film transistor substrate according to claim 2, wherein the second semiconductor layer is arranged directly on the gate insulation film.

6. The thin film transistor substrate according to claim 2, wherein the first electrode and the second electrode are ohmically connected to the first semiconductor layer via the first contact layer and the second contact layer, respectively.

7. The thin film transistor substrate according to claim 6, wherein the first contact layer and the second contact layer are formed of an n-type semiconductor having electron carrier density of 1×10¹² cm⁻³ or more and 1×10¹⁹ cm⁻³ or less.

8. The thin film transistor substrate according to claim 2, wherein the first electrode has an edge arranged on the first contact layer separately away from an edge of the first contact layer, the second electrode has an edge arranged on the second contact layer separately away from an edge of the second contact layer, and the third electrode and the fourth electrode each have an edge arranged on the second semiconductor layer separately away from an edge of the second semiconductor layer.

9. The thin film transistor substrate according to claim 2, wherein the gate insulation film comprises a nitride film and an oxide film that are stacked mutually, the first semiconductor layer is arranged directly on the nitride film, and the second semiconductor layer is arranged directly on the oxide film.

10. The thin film transistor substrate according to claim 2, further comprising:
a common electrode provided on the substrate and separated away from the first gate electrode and the second gate electrode;
an interlayer insulation film provided on the pixel electrode; and
a counter electrode provided on the interlayer insulation film.

11. A method of manufacturing a thin film transistor substrate, the method comprising:
forming a first conductive film on a substrate;
providing a pattern to the first conductive film such that a first gate electrode and a second gate electrode are formed;
forming a gate insulation film on the first gate electrode and the second gate electrode;
forming an amorphous silicon film on the gate insulation film;
providing a pattern to the amorphous silicon film such that a first semiconductor layer opposed to the first gate electrode with intermediation of the gate insulation film is formed;
forming an oxide semiconductor film on the gate insulation film on which the first semiconductor layer is provided;
providing a pattern to the oxide semiconductor film;
forming a second conductive film on the gate insulation film on which the first semiconductor layer and the oxide semiconductor film are provided;
providing a pattern to the second conductive film, the providing a pattern to the oxide semiconductor film and the providing a pattern to the second conductive film including
forming, from the oxide semiconductor film, a first contact layer having a portion arranged on the first semiconductor layer, a second contact layer having a portion arranged on the first semiconductor layer separately away from the first contact layer, and a second semiconductor layer provided on the gate insulation film and opposed to the second gate electrode with intermediation of the gate insulation film, and
forming, from the second conductive film, a first electrode connected to the first contact layer, a second electrode connected to the second contact layer, a third electrode having a portion arranged on the second semiconductor layer, and a fourth electrode having a portion arranged on the second semiconductor layer separately away from the third electrode; and
forming a pixel electrode connected to the second electrode.

12. The method of manufacturing a thin film transistor substrate according to claim 11, wherein the providing a pattern to the oxide semiconductor film and the providing a pattern to the second conductive film comprise:
forming, on the second conductive film, a photoresist layer having a first opening, a first region, and a second region having a thickness larger than a thickness of the first region;
forming the first electrode and the second electrode by etching the second conductive film in the first opening of the photoresist layer;
forming, after the forming the first electrode and the second electrode, the first contact layer and the second contact layer by etching the oxide semiconductor film in the first opening of the photoresist layer;
changing, after the forming the first contact layer and the second contact layer, the first region into a second opening by at least partially reserving the second region through partial removal of the photoresist layer; and
forming the third electrode and the fourth electrode by etching the second conductive film in the second opening of the photoresist layer.

13. The method of manufacturing a thin film transistor substrate according to claim 11, wherein the forming the gate insulation film includes forming a first nitride film, forming an oxide film on the first nitride film, and forming a second nitride film on the oxide film, and
the method of manufacturing a thin film transistor substrate further comprises reserving, before the forming the oxide semiconductor film, a first portion of the second nitride film positioned between the first semiconductor layer and the oxide film, and removing a second portion of the second nitride film other than the first portion.

14. The method of manufacturing a thin film transistor substrate according to claim 11, wherein the providing a pattern to the first conductive film is performed such that a common electrode separated away from the first gate electrode and the second gate electrode is formed on the substrate, and
the method of manufacturing a thin film transistor substrate further comprises:
forming an interlayer insulation film on the pixel electrode; and
forming, on the interlayer insulation film, a counter electrode connected to the common electrode.

15. A liquid crystal display comprising:
a thin film transistor substrate including a display region in which a first transistor having a channel layer formed of amorphous silicon is provided, and a frame region in which a second transistor having a channel layer formed of an oxide semiconductor is provided, the frame region being arranged outside the display region;
an opposing substrate being opposed to the thin film transistor substrate with a gap therebetween, and having light transmitting property;
a liquid crystal layer arranged in the gap between the thin film transistor substrate and the opposing substrate; and
a light shielding layer provided partially on the opposing substrate so as to be opposed to the frame region.
